(19) United States
(12) Patent Application Publication
(10) Pub. No.: US 2018/0362763 A1
(43) Pub. Date: Dec. 20, 2018

(54) RESIN COMPOSITION, METHOD FOR PRODUCING RESIN, METHOD FOR PRODUCING RESIN FILM, AND METHOD FOR PRODUCING ELECTRONIC DEVICE

(71) Applicant: TORAY INDUSTRIES, INC., TOKYO (JP)

(72) Inventors: Daichi Miyazaki, Otsu-shi, Shiga (JP); Junji Wakita, Chuo-ku, Tokyo (JP); Takashi Tokuda, Otsu-shi, Shiga (JP); Yasuko Tachibana, Otsu-shi, Shiga (JP); Koji Ueoka, Otsu-shi, Shiga (JP); Tomoki Ashibe, Otsu-shi, Shiga (JP)

(73) Assignee: TORAY INDUSTRIES, INC., TOKYO (JP)

(21) Appl. No.: 15/781,886

(22) PCT Filed: Dec. 8, 2016
(86) PCT No.: PCT/JP2016/086593

§ 371 Date: Jun. 6, 2018

(30) Foreign Application Priority Data
Dec. 11, 2015 (JP) 2015-241899
Dec. 11, 2015 (JP) 2015-241900
Feb. 3, 2016 (JP) 2016-018605

(51) Int. Cl. C08L 79/08; C08G 73/10; H01L 51/50; H01L 51/00

(52) U.S. Cl. CPC C08L 79/08; C08G 73/1007; H01L 51/50; C08K 5/09; C08L 2203/20; C08L 2203/16; H01L 51/0053

(57) ABSTRACT

A resin composition includes an (a) resin having a structure represented by Chemical Formula (1); and a (b) solvent.

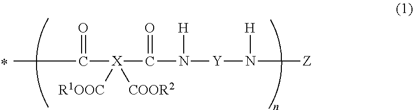

The resin composition also includes an amount of a compound represented by Chemical Formula (3) which is 0.1 ppm by mass or more and 40 ppm by mass or less.

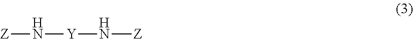

### CROSS REFERENCE TO RELATED APPLICATIONS

This is the U.S. National Phase application of PCT/JP2016/086593, filed Dec. 8, 2016, which claims priority to Japanese Patent Application No. 2015-241899, filed Dec. 11, 2015, Japanese Patent Application No. 2015-241900, filed Dec. 11, 2015 and Japanese Patent Application No. 2016-018605, filed Feb. 3, 2016, the disclosures of these applications being incorporated herein by reference in their entireties for all purposes.

### TECHNICAL FIELD OF THE INVENTION

The present invention relates to a resin composition, a method for producing a resin, a method for producing a resin film, and a method for producing an electronic device.

### BACKGROUND OF THE INVENTION

Polyimide is used as a material for various electronic devices such as semiconductors and display applications due to its excellent electrical insulating properties, heat resistance, and mechanical properties. Recently, flexible image display devices having excellent resistance to impact have been capable of being produced by using heat resistant resin films for the substrates of the flexible image display devices such as organic EL displays, electronic papers, and color filters.

When the polyimide is used as the material for the electronic devices, a solution containing a polyamic acid being a polyimide precursor is usually used. Typically, the polyimide is obtained by applying the solution containing a polyamic acid to the substrate and imidizing the polyamic acid by baking the coating film.

In general, in order to improve the mechanical properties of the polyimide film such as maximum tensile stress and elongation, an increase in a degree of polymerization of the polyimide is effective. However, the increase in the degree of polymerization of the polyamic acid being a polyimide precursor increases the viscosity of the polymerization solution and thus control of the viscosity suitable for application is difficult.

Therefore, a method for controlling the degree of polymerization of the polyamic acid by protecting the amino groups and acid anhydride groups in the polyamic acid terminal has been reported (For example, refer to Patent Literatures 1 and 2). When these polyamic acids are heated, terminal protective groups are eliminated to regenerate the amino groups or acid anhydride groups. The regenerated amino groups or the acid anhydride groups can be involved in the polymerization. As a result, the degree of polymerization of the polyimide is increased, and thus the mechanical properties of the polyimide film are improved.

### CITATION LIST

### Patent Literature

Patent Literature 1: Japanese Patent Application Laid-open No. 2009-109589

Patent Literature 2: Japanese Patent Application Laid-open No. 2000-234023

### SUMMARY OF THE INVENTION

However, the method described in Patent Document 1 has a problem in that particles increase during storage of the solution containing a polyamic acid. Moreover, the methods described in Patent Literature 1 and 2 also have a problem in that the viscosity greatly changes during storage of the solution containing a polyamic acid.

Accordingly, an object of the present invention is to provide a resin composition that generates fewer particles and provides a polyimide film having high mechanical properties after baking, a method for producing a resin, a method for producing a resin film, and a method for producing an electronic device. Moreover, an object of the present invention is to provide a resin composition that has extremely high viscosity stability when the resin composition is used as a varnish and provides a polyimide film having high mechanical properties after baking, a method for producing a resin, a method for producing a resin film, and a method for producing an electronic device.

The inventors of the present invention have found that generation of particles is caused by a low molecular weight compound generated as a by-product in the process of producing a polyamic acid in which amino groups are protected. As a means for solving this problem, the present invention has been achieved.

A first aspect of the resin composition according to the present invention is a resin composition including:

an (a) resin having a structure represented by Chemical Formula (1);

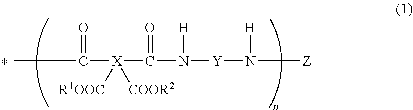

(in Chemical Formula (1), X represents a tetravalent tetracarboxylic acid residue having two or more carbon atoms and Y represents a divalent diamine residue having two or more carbon atoms; Z represents a structure represented by Chemical Formula (2); n represents a positive integer; R¹ and R² each independently represent a hydrogen atom, a hydrocarbon group having 1 to 10 carbon atoms, an alkylsilyl group having 1 to 10 carbon atoms, an alkali metal ion, an ammonium ion, an imidazolium ion, or a pyridinium ion; and * indicates that the carbon atom is bonded to another atom),

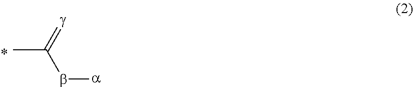

(in Chemical Formula (2), a represents a monovalent hydrocarbon group having 2 or more carbon atoms and β and γ each independently represent an oxygen atom or a sulfur atom; and * indicates a bonding point of Z in Chemical Formula (1)); and

a (b) solvent, wherein

an amount of a compound represented by Chemical Formula (3) is 0.1 ppm by mass or more and 40 ppm by mass or less,

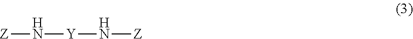

(in Chemical Formula (3), Y represents a divalent diamine residue having 2 or more carbon atoms; and Z represents a structure represented by Chemical Formula (2)).

A second aspect of the resin composition according to the present invention is a resin composition including: an (a′) resin having a repeating unit represented by Chemical Formula (4) as a main component; and a (b) solvent. The (a′) resin includes one or more resins selected from a group consisting of the following (A) and (B):

(A) a resin mixture comprising a resin (A-1) comprising two or more partial structures represented by Chemical Formula (5) in a molecule and a resin (A-2) comprising two or more partial structures represented by Chemical Formula (6) in a molecule; and

(B) a resin comprising one or more partial structures represented by Chemical Formula (5) and one or more partial structures represented by Chemical Formula (6) in a molecule,

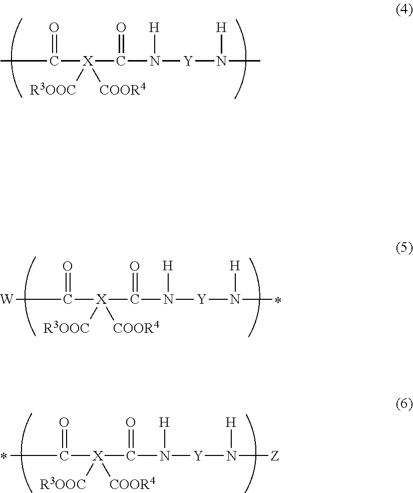

tin Chemical Formulas (4) to (6), X represents a tetravalent tetracarboxylic acid residue having two or more carbon atoms and Y represents a divalent diamine residue having two or more carbon atoms; in Chemical Formula (5), W represents a structure represented by Chemical Formula (7); Z represents a structure represented by Chemical Formula (2); R³ and R⁴ each independently represent a hydrogen atom, a hydrocarbon group having 1 to 10 carbon atoms or an alkylsilyl group having 1 to 10 carbon atoms, an alkali metal ion, an ammonium ion, an imidazolium ion, or a pyridinium ion; and * in Chemical Formulas (5) and (6) indicates that the nitrogen/carbon atom is bonded to another atom),

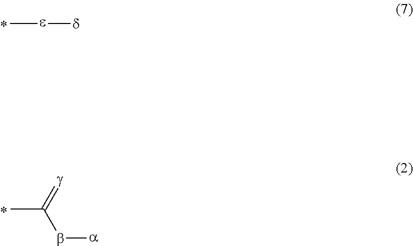

(δ in Chemical Formula (7) and α in Chemical Formula (2) each independently represent a monovalent hydrocarbon group having two or more carbon atoms; ε in Chemical Formula (7) and 3 and γ in Chemical Formula (2) each independently represent an oxygen atom or a sulfur atom; * in Chemical Formula (7) indicates a bonding point of W in Chemical Formula (5) and * in Chemical Formula (2) indicates a bonding point of Z in Chemical Formula (6)).

In the second aspect, unprotected acid anhydride groups or amino groups are not present at the terminal of the resin or the amount of these groups are small even if these groups are present. Therefore, the resin composition including the polyamic acid according to the second aspect according to the present invention has high viscosity stability during storage as a varnish. This is because, although the unprotected acid anhydride groups and the unprotected amino groups can react with moisture in the resin composition and oxygen in the atmosphere, respectively, these reactions are reduced in the polyamic acid resin composition according to the present invention.

According to the present invention, the resin composition that generates fewer particles and provides a polyimide film having high mechanical properties after baking is obtained. Moreover, a resin composition that has high viscosity stability during storage when the resin composition is used as a varnish and provides a polyimide film having high mechanical properties after baking is obtained.

### DETAILED DESCRIPTION OF CERTAIN EMBODIMENTS OF THE INVENTION

The first aspect of the resin composition according to the present invention is a resin composition including (a) a resin having a structure represented by Chemical Formula (1);

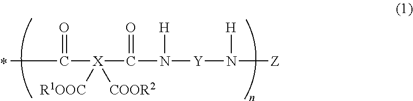

in Chemical Formula (1), X represents a tetravalent tetracarboxylic acid residue having two or more carbon atoms and Y represents a divalent diamine residue having two or more carbon atoms, Z represents a structure represented by Chemical Formula (2), n represents a positive integer, R¹ and R² each independently represent a hydrogen atom, a hydrocarbon group having 1 to 10 carbon atoms, an alkylsilyl group having 1 to 10 carbon atoms, an alkali metal ion, an ammonium ion, an imidazolium ion, or a pyridinium ion, and * indicates that the carbon atom is bonded to another atom;

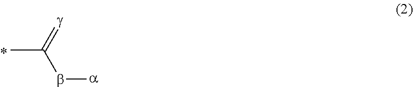

in Chemical Formula (2), α represents a monovalent hydrocarbon group having 2 or more carbon atoms, β and γ each independently represent an oxygen atom or a sulfur atom, and * indicates a bonding point of Z in Chemical Formula (1); and

(b) a solvent, in which the amount of a compound represented by Chemical Formula (3) included in the resin composition is 0.1 ppm by mass or more and 40 ppm by mass or less.

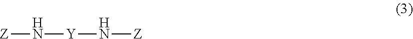

In Chemical Formula (3), Y represents a divalent diamine residue having 2 or more carbon atoms. Z represents a structure represented by Chemical Formula (2).

The second aspect of the resin composition according to the present invention is a resin composition including an (a′) resin having a repeating unit represented by Chemical Formula (4) as a main component and a (b) solvent, in which the resin includes one or more resins selected from the group consisting of (A) and (B):

(A) a resin mixture including a resin (A-1) including two or more partial structures represented by Chemical Formula (5) in a molecule and a resin (A-2) including two or more partial structures represented by Chemical Formula (6) in a molecule; and

(B) a resin including one or more partial structures represented by Chemical Formula (5) and one or more partial structures represented by Chemical Formula (6) in a molecule.

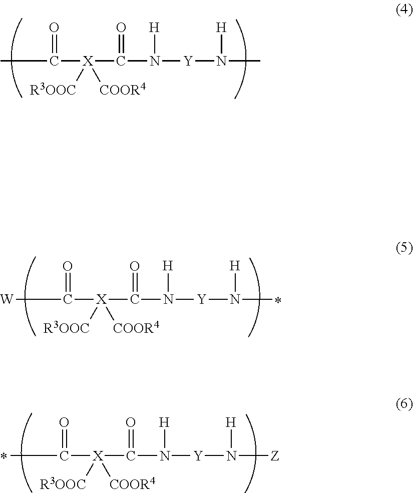

In Chemical Formulas (4) to (6), X is a tetravalent tetracarboxylic acid residue having two or more carbon atoms and Y represents a divalent diamine residue having two or more carbon atoms. In Chemical Formula (5), W represents a structure represented by Chemical Formula (7). Z represents a structure represented by Chemical Formula (2). R³ and R⁴ each independently represent a hydrogen atom, a hydrocarbon group having 1 to 10 carbon atoms or an alkylsilyl group having 1 to 10 carbon atoms, an alkali metal ion, an ammonium ion, an imidazolium ion, or a pyridinium ion. * in Chemical Formulas (5) and (6) indicates that the nitrogen/carbon atom is bonded to another atom.

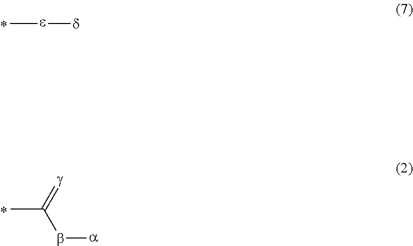

δ in Chemical Formula (7) and α in Chemical Formula (2) each independently represent a monovalent hydrocarbon group having two or more carbon atoms. ε in Chemical Formula (7) and β and γ in Chemical Formula (2) each independently represent an oxygen atom or a sulfur atom. * in Chemical Formula (7) indicates the bonding point of W in Chemical Formula (5). * in Chemical Formula (2) indicates the bonding point of Z in Chemical Formula (6).

First, the first aspect of the resin composition according to the present invention will be described.

(a) Resin having structure represented by Chemical Formula (1)

Chemical Formula (1) represents the structure of a polyamic acid. As described below, the polyamic acid is obtained by reacting a tetracarboxylic acid and a diamine compound. Further, the polyamic acid can be converted into a polyimide being a heat resistant resin by carrying out heating or chemical treatment.

In Chemical Formula (1), X is preferably a tetravalent hydrocarbon group having 2 to 80 carbon atoms. X may also be a tetravalent organic group containing hydrogen atoms and carbon atoms as essential components and having 2 to 80 carbon atoms containing one or more atoms selected from the group consisting of boron, oxygen, sulfur, nitrogen, phosphorus, silicon, and halogen. Each of the atoms of boron, oxygen, sulfur, nitrogen, phosphorus, silicon, and halogen is independently preferably in the range of 20 or less and more preferably in the range of 10 or less.

Examples of the tetracarboxylic acid that provides X may include the following.

Examples of aromatic tetracarboxylic acids include monocyclic aromatic tetracarboxylic acid compounds such as pyromellitic acid and 2,3,5,6-pyridine tetracarboxylic acid; the various isomers of biphenyl tetracarboxylic acids such as 3,3′,4,4′-biphenyltetracarboxylic acid, 2,3,3′,4′-biphenyltetracarboxylic acid, 2,2′,3,3′-biphenyltetracarboxylic acid, 3,3′,4,4′-benzophenonetetracarboxylic acid, and 2,2′,3,3′-benzophenone tetracarboxylic acid;

bis(dicarboxyphenyl) compound such as 2,2-bis(3,4-dicarboxyphenyl)hexafluoropropane, 2,2-bis(2,3-dicarboxyphenyl)hexafluoropropane, 2,2-bis(3,4-dicarboxyphenyl)propane, 2,2-bis(2,3-dicarboxyphenyl)propane, 1,1-bis(3,4-dicarboxyphenyl)ethane, 1,1-bis(2,3-dicarboxyphenyl)ethane, bis(3,4-dicarboxyphenyl)methane, bis(2,3-dicarboxyphenyl)methane, bis(3,4-dicarboxyphenyl)sulfone, and bis(3,4-dicarboxyphenyl)ether;

bis(dicarboxyphenoxyphenyl) compounds such as 2,2-bis[4-(3,4-dicarboxyphenoxy)phenyl]hexafluoropropane, 2,2-bis[4-(2,3-dicarboxyphenoxy)phenyl]hexafluoropropane, 2,2-bis[4-(3,4-dicarboxyphenoxy)phenyl]propane, 2,2-bis[4-(2,3-dicarboxyphenoxy)phenyl]propane, 2,2-bis[4-(3,4-dicarboxyphenoxy)phenyl]sulfone, and 2,2-bis[4-(3,4-dicarboxyphenoxy)phenyl] ether.

Various isomers of naphthalene tetracarboxylic acids or condensed polycyclic aromatic tetracarboxylic acids such as 1,2,5,6-naphthalene tetracarboxylic acid, 1,4,5,8-naphthalene tetracarboxylic acid, 2,3,6,7 naphthalene tetracarboxylic acid, and 3,4,9,10-perylene tetracarboxylic acid; and

bis(trimellitic acid monoester) compounds such as p-phenylene-bis(trimellitic acid monoester), p-biphenylene-bis(trimellitic acid monoester), ethylene-bis(trimellitic acid monoester), and bisphenol A-bis(trimellitic acid monoester).

Examples of aliphatic tetracarboxylic acid include chain aliphatic tetracarboxylic acid compounds such as butane tetracarboxylic acid; and

alicyclic tetracarboxylic acid compounds such as cyclobutane tetracarboxylic acid, 1,2,3,4-cyclopentane tetracarboxylic acid, 1,2,4,5-cyclohexane tetracarboxylic acid, bicyclo[2.2.1.]heptane tetracarboxylic acid, bicyclo[3.3.1.] tetracarboxylic acid, bicyclo[3.1.1.]hept-2-ene tetracarboxylic acid, bicyclo[2.2.2.]octane tetracarboxylic acid, and adamantane tetracarboxylic acid.

These tetracarboxylic acids may be used as they are or in a state of an acid anhydride, an activated ester, or an activated amide. Among these, the acid anhydrides are preferably used because by-products are not generated at the time of polymerization. In addition, these compounds may be used in combination of two or more of them.

As described below, the aromatic tetracarboxylic acid is preferably used in 50 mol % or more relative to the total tetracarboxylic acids from the viewpoint of the heat resistance of the resin film obtained by curing the resin having the structure represented by Chemical Formula (1). Among them, X preferably includes a tetravalent tetracarboxylic acid residue represented by Chemical Formulas (11) or (12) as the main component.

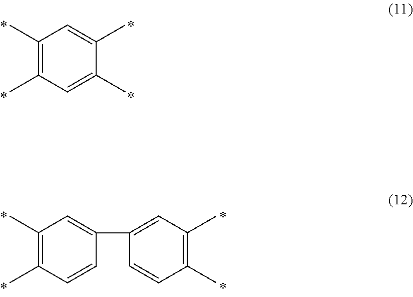

* in Chemical Formulas (11) and (12) indicates the bonding point of X in Chemical Formula (1).

In other words, pyromellitic acid or 3,3′,4,4′-biphenyltetracarboxylic acid is preferably used as the main component. The term “main component” as used herein means that the component is included in 50 mol % or more in the total tetracarboxylic acids. More preferably, the main component is included in 80 mol % or more. When the resin in which these tetracarboxylic acids are used as the main component is used, the resin film obtained by curing the resin has a small linear thermal expansion coefficient and thus the resin film can be used as a substrate for a display.

In addition, in order to improve application properties to the support and resistance to oxygen plasma and UV ozone treatment used in washing and the like, silicon-containing tetracarboxylic acids such as dimethylsilane diphthalate and 1,3-bis(phthalic acid) tetramethyldisiloxane may be used. When the silicon-containing tetracarboxylic acid is used, the silicon-containing tetracarboxylic acid is preferably used in 1 mol % to 30 mol % relative to the total tetracarboxylic acids.

A part of the hydrogen atoms contained in the residue of the tetracarboxylic acid exemplified above may be substituted with hydrocarbon groups having 1 to 10 carbon atoms such as a methyl group or an ethyl group, fluoroalkyl groups having 1 to 10 carbon atoms such as a trifluoromethyl group, and groups such as F, Cl, Br, I. Furthermore, when the tetracarboxylic acid is substituted with an acidic group such as OH, COOH, SO₃H, CONH₂, and O₂NH₂, the solubility of the resin into an alkali aqueous solution is improved, and thus this substitution is preferable in the case of use as a photosensitive resin composition described below.

In Chemical Formula (1), Y is preferably a divalent hydrocarbon group having 2 to 80 carbon atoms. Y may also be a divalent organic group containing hydrogen atoms and carbon atoms as essential components and having 2 to 80 carbon atoms containing one or more atoms selected from the group consisting of boron, oxygen, sulfur, nitrogen, phosphorus, silicon, and halogen. Each of the atoms of boron, oxygen, sulfur, nitrogen, phosphorus, silicon, and halogen is independently preferably in the range of 20 or less and more preferably in the range of 10 or less.

Examples of diamine that provides Y may include the following.

Examples of the diamine compounds having an aromatic ring include monocyclic aromatic diamine compounds such as m-phenylenediamine, p-phenylenediamine, and 3,5-diaminobenzoic acid;

naphthalene diamine compounds or condensed polycyclic aromatic diamine compounds such as 1,5-naphthalenediamine, 2,6-naphthalenediamine, 9,10-anthracenediamine, and 2,7-diaminofluorene;

bis(diaminophenyl) compounds or various derivatives thereof such as 4,4′-diaminobenzanilide, 3,4′-diaminodiphenyl ether, 4,4′-diaminodiphenyl ether, 3-carboxy-4,4′-diaminodiphenyl ether, 3-sulfonic acid-4,4′-diaminodiphenyl ether, 3,4′-diaminodiphenylmethane, 4,4′-diaminodiphenylmethane, 3,4′-diaminodiphenylsulfone, 4,4′-diaminodiphenylsulfone, 3,4′-diaminodiphenylsulfide, 4,4′-diaminodiphenylsulfide, 4-aminobenzoic acid 4-aminophenyl ester, 9,9-bis(4-aminophenyl)fluorene, and 1,3-bis(4-anilino)tetramethyldisiloxane;

4,4′-diaminobiphenyl or various derivatives thereof such as 4,4′-diaminobiphenyl, 2,2′-dimethyl-4,4′-diaminobiphenyl, 2,2′-diethyl-4,4′-diaminobiphenyl, 3,3′-dimethyl-4,4′-diaminobiphenyl, 3,3′-diethyl-4,4′-diaminobiphenyl, 2,2′,3,3′-tetramethyl-4,4′-diaminobiphenyl, 3,3′,5,5′-tetramethyl-4,4′-diaminobiphenyl, and 2,2′-di(trifluoromethyl)-4,4′-diaminobiphenyl;

bis(aminophenoxy) compounds such as bis(4-aminophenoxyphenyl)sulfone, bis(3-aminophenoxyphenyl)sulfone, bis(4-aminophenoxy)biphenyl, bis[4-(4-aminophenoxy)phenyl]ether, 2,2-bis[4-(4-aminophenoxy)phenyl]propane, 2,2-bis[4-(4-aminophenoxy)phenyl]hexafluoropropane, 1,4-bis(4-aminophenoxy)benzene, 1,3-bis(3-aminophenoxy)benzene, and 1,3-bis(4-aminophenoxy)benzene;

bis(3-amino-4-hydroxyphenyl) compounds such as bis(3-amino-4-hydroxyphenyl)hexafluoropropane, bis(3-amino-4-hydroxyphenyl)sulfone, bis(3-amino-4-hydroxyphenyl)propane, bis(3-amino-4-hydroxyphenyl)methylene, bis(3-amino-4-hydroxyphenyl) ether, bis(3-amino-4-hydroxy)biphenyl, and 9,9-bis(3-amino-4-hydroxyphenyl)fluorene;

bis(aminobenzoyl) compounds such as 2,2′-bis[N-(3-aminobenzoyl)-3-amino-4-hydroxyphenyl]hexafluoropropane, 2,2′-bis[N-(4-aminobenzoyl)-3-amino-4-hydroxyphenyl]hexafluoropropane, 2,2′-bis[N-(3-aminobenzoyl)-3-amino-4-hydroxyphenyl]propane, 2,2′-bis[N-(4-aminobenzoyl)-3-amino-4-hydroxyphenyl]propane, bis[N-(3-aminobenzoyl)-3-amino-4-hydroxyphenyl]sulfone, bis[N-(4-aminobenzpyl)-3-amino-4-hydroxyphenyl]sulfone, 9,9-bis[N-(3-aminobenzoyl)-3-amino-4-hydroxyphenyl]fluorene, 9,9-bis[N-(4-aminobenzoyl)-3-amino-4-hydroxyphenyl]fluorene, N,N′-bis(3-aminobenzoyl)-2,5-diamino-1,4-dihydroxybenzene, N,N′-bis(4-aminobenzoyl)-2,5-diamino-1,4-dihydroxybenzene, N,N′-bis(3-aminobenzoyl)-4,4′-diamino-3,3′-dihydroxybiphenyl, N,N′-bis(4-aminobenzoyl)-4,4′-diamino-3,3′-dihydroxybiphenyl, N,N′-bis(3-aminobenzoyl)-3,3′-diamino-4,4-dihydroxybiphenyl, and N,N′-bis(4-aminobenzoyl)-3,3′-diamino-4,4-dihydroxybiphenyl; and

heterocyclic ring-containing diamine compounds such as 2-(4-aminophenyl)-5-aminobenzoxazole, 2-(3-aminophenyl)-5-aminobenzoxazole, 2-(4-aminophenyl)-6-aminobenzoxazole, 2-(3-aminophenyl)-6-aminobenzoxazole, 1,4-bis(5-amino-2-benzoxazolyl)benzene, 1,4-bis(6-amino-2-benzoxazolyl)benzene, 1,3-bis(5-amino-2-benzoxazolyl)benzene, 1,3-bis(6-amino-2-benzoxazolyl)benzene, 2,6-bis(4-aminophenyl)benzobisoxazole, 2,6-bis(3-aminophenyl)benzobisoxazole, 2,2′-bis[(3-aminophenyl)-5-benzoxazolyl]hexafluoropropane, 2,2′-bis[(4-aminophenyl)-5-benzoxazolyl]hexafluoroprane, bis[(3-aminophenyl)-5-benzoxazolyl], bis[(4-aminophenyl)-5-benzoxazolyl], bis[(3-aminophenyl)-6-benzoxazolyl], and bis[(4-aminophenyl)-6-benzoxazolyl]; or

a compound in which a part of hydrogen atoms bonded to the aromatic ring contained in these diamine compounds is substituted with a hydrocarbon group or halogen.

Examples of the aliphatic diamine compound include straight chain diamine compounds such as ethylenediamine, propylenediamine, butanediamine, pentanediamine, hexanediamine, octanediamine, nonanediamine, decanediamine, undecanediamine, dodecanediamine, tetramethylhexanediamine, 1,12-(4,9-dioxa)dodecanediamine, 1,8(3,6-dioxa)octanediamine, and 1,3-bis(3-aminopropyl)tetramethyldisiloxane;

alicyclic diamine compounds such as cyclohexanediamine, 4,4′-methylenebis(cyclohexylamine), and isophoronediamine; and

polyoxyethylene amines and polyoxypropylene amines known as Jeffamine (trade name, manufactured by Huntsman Corporation) and the copolymerized compounds thereof.

These diamines may be used as they are or in a state of corresponding trimethylsilylated diamines. In addition, these compounds may be used in combination of two or more of them.

As described below, the aromatic diamine compound is preferably used in 50 mol % or more relative to the total diamine compounds from the viewpoint of the heat resistance of the resin film obtained by curing the resin having the structure represented by Chemical Formula (1). Among them, Y preferably includes a divalent diamine residue represented by Chemical Formula (13) as the main component.

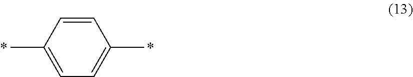

* in Chemical Formula (13) indicates the bonding point of Y in Chemical Formula (1).

In other words, p-phenylenediamine is preferably used as the main component. The term “main component” as used herein means that the component is included in 50 mol % or more in the total diamine compounds. More preferably, the component is included in 80 mol % or more. When the resin in which p-phenylenediamine is used as the main component is used, the resin film obtained by curing the resin has a small linear thermal expansion coefficient and thus the resin film can be used as a substrate for a display.

The structure in which X in Chemical Formula (1) includes the tetravalent tetracarboxylic acid residue represented by Chemical Formula (11) or Chemical Formula (12) as the main component and Y includes the divalent diamine residue represented by Chemical Formula (13) as the main component is particularly preferable.

In addition, in order to improve application properties to the support and resistance to oxygen plasma and UV ozone treatment used in washing and the like, silicon-containing diamines such as 1,3-bis(3-aminopropyl)tetramethyldisiloxane and 1,3-bis(4-anilino)tetramethyldisiloxane may be used. When the silicon-containing diamine compound is used, the silicon-containing diamine compound is preferably used in 1 mol % to 30 mol % relative to the total diamine compounds.

A part of the hydrogen atoms contained in the residue of the diamine compound exemplified above may be substituted with hydrocarbon groups having 1 to 10 carbon atoms such as a methyl group or an ethyl group, fluoroalkyl groups having 1 to 10 carbon atoms such a trifluoromethyl group, and groups such as F, Cl, Br, I. Furthermore, when the tetracarboxylic acid is substituted with an acidic group such as OH, COOH, SO₃H, CONH₂, and SO₂NH₂, the solubility of the resin into an alkali aqueous solution is improved, and thus this substitution is preferable in the case of use as a photosensitive resin composition described below.

In Chemical Formula (1), Z represents the terminal structure of the resin and represents a structure represented by Chemical Formula (2). In Chemical Formula (2), a is preferably a monovalent hydrocarbon group having 2 to 10 carbon atoms. α is preferably an aliphatic hydrocarbon group and may be any one of a linear hydrocarbon group, a branched hydrocarbon group, and a cyclic hydrocarbon group. Examples of the hydrocarbon group include straight chain hydrocarbon groups such as an ethyl group, a n-propyl group, a n-butyl group, a n-pentyl group, a n-hexyl group, a n-heptyl group, a n-octyl group, a n-nonyl group, and a n-decyl group, branched chain hydrocarbon groups such as an isopropyl group, an isobutyl group, a sec-butyl group, a tert-butyl group, an isopentyl group, a sec-pentyl group, a tert-pentyl group, an isohexyl group, and a sec-hexyl group, and cyclic hydrocarbon groups such as a cyclopropyl group, a cyclobutyl group, a cyclopentyl group, a cyclohexyl group, a cycloheptyl group, a cyclooctyl group, a norbornyl group, and an adamantyl group.

Among these hydrocarbon groups, a monovalent branched hydrocarbon group and cyclic hydrocarbon group having 2 to 10 carbon atoms are preferable. An isopropyl group, a cyclohexyl group, a tert-butyl group, and tert-pentyl group are more preferable, and tert-butyl group is the most preferable.

In Chemical Formula (2), β and γ each independently represent an oxygen atom or a sulfur atom and preferably represent an oxygen atom.

When the resin having the structure represented by Chemical Formula (1) is heated, Z is thermally decomposed to generate an amino group at the terminal of the resin. The amino group generated at the terminal can react with another resin having a tetracarboxylic acid at the terminal. Therefore, when the resin having the structure represented by Chemical Formula (1) is heated, the polyimide resin having a high degree of polymerization is obtained.

The concentration of the resin having the structure represented by Chemical Formula (1) in the resin composition is preferably 3% by mass or more and more preferably 5% by mass or more relative to 100% by mass of the resin composition. The concentration is preferably 40% by mass or less and more preferably 30% by mass or less. When the concentration of the resin is 3% by mass or more, the thickness of the resin film is easy to increase, whereas when the concentration of the resin is 40% by mass or less, uniform resin film is easily obtained due to sufficient dissolution of the resin in the resin composition.

The weight average molecular weight of the resin having the structure represented by Chemical Formula (1) measured with gel permeation chromatography in terms of polystyrene is preferably 200,000 or less, more preferably 150,000 or less, and further preferably 100,000 or less. When the weight average molecular weight is within this range, an increase in viscosity can be further reduced even at high concentration of the resin composition. In addition, the weight average molecular weight is preferably 2,000 or more, more preferably 3,000 or more, and further preferably 5,000 or more. When the weight average molecular weight is 2,000 or more, the viscosity when the resin composition is formed is not excessively lowered, and thus more favorable application properties can be retained.

In Chemical Formula (1), n represents the number of repetitions of structural units of the resin and may be in a range that satisfies the above weight average molecular weight. n is preferably 5 or more and more preferably 10 or more. In addition, n is preferably 1000 or less and more preferably 500 or less.

(Compound Represented by Chemical Formula (3))

The compound represented by Chemical Formula (3) is a compound in which one hydrogen atom is substituted with Z, that is, a structure represented by Chemical Formula (2) for both of the two amino groups contained in the diamine compound.

As described below, a compound represented by Chemical Formula (3) is generated as a by-product during the process for producing the resin having the structure represented by Chemical Formula (1). The inventors of the present invention have found through investigation that the compound of Chemical Formula (3) has low solubility in solvents and thus is precipitated in the resin composition as time passes to form particles. The generated particles remain in the heat resistant resin film obtained from the resin composition, resulting in lowering the tensile elongation and maximum tensile stress of the heat resistant resin film. In addition, the unevenness on the surface of the heat resistant resin film is generated by the particles and thus performance may be deteriorated when an electronic device is formed on the heat resistant resin film.

Therefore, by decreasing the content of the compound represented Chemical Formula (3) in the resin composition, the heat resistant resin film generating fewer particles and having high mechanical properties after baking is obtained. Moreover, the heat resistant resin film having a smooth surface is obtained and thus an electronic device having high performance can be obtained when the electronic device is formed on the heat resistant resin film.

Specifically, the amount of the compound represented by Chemical Formula (3) contained in the resin composition is 40 ppm by mass or less, more preferably 20 ppm by mass or less, and further preferably 10 ppm by mass or less. When the amount is more than 40 ppm by mass, the generation of particles as described above is observed.

In addition, the amount of the compound represented by Chemical Formula (3) contained in the resin composition is preferably 0.1 ppm by mass or more, more preferably 0.5 ppm by mass or more, and further preferably 1 ppm by mass or more. When the amount is 0.1 ppm by mass or more, workability is not deteriorated in the production of the resin composition.

In addition, the structure represented by Chemical Formula (2) is decomposed by an acid. Therefore, by an acid contaminated from the environment in the production process of the resin composition according to the present invention, the structure represented by Chemical Formula (2) may be decomposed. In other words, Z in Chemical Formula (1) is decomposed to change the viscosity of the resin composition. On the other hand, the compound represented by Chemical Formula (3) is present in the resin composition and acts as a trap for the acid. Therefore, when the amount of the compound represented by Chemical Formula (3) contained in the resin composition is 4 ppm by mass or more, the stability of the polyamic acid during storage is high.

The content of the compound represented by Chemical Formula (3) can be measured with a liquid chromatograph-mass spectrometer. Y and Z in Chemical Formula (3) is the same as Y and Z in Chemical Formula (1).

For (b) the solvent contained in the resin composition according to the first aspect of the present invention will be described below

Subsequently, the (a′) resin including the repeating units represented by Chemical Formula (4) as the main component and selected from the group consisting of (A) and (B) that is the second aspect of the resin composition according to the present invention will be described.

(a′) Resin Having the Repeating Units Represented by Chemical Formula (4) as Main Component

Chemical Formula (4) represents the repeating units of the polyamic acid. The polyamic acid, as described below, is obtained by reacting a tetracarboxylic acid and a diamine compound. Further, the polyamic acid can be converted into a polyimide being a heat resistant resin by carrying out heating and chemical treatment.

In Chemical Formula (4), X is preferably a tetravalent hydrocarbon group having 2 to 80 carbon atoms. X may also be a tetravalent organic group containing hydrogen atoms and carbon atoms as essential components and having 2 to 80 carbon atoms containing one or more atoms selected from the group consisting of boron, oxygen, sulfur, nitrogen, phosphorus, silicon, and halogen. Each of the atoms of boron, oxygen, sulfur, nitrogen, phosphorus, silicon, and halogen is independently preferably in the range of 20 or less and more preferably in the range of 10 or less.

Examples of the tetracarboxylic acid that provides X may include the same tetracarboxylic acid as the examples of the tetracarboxylic acids of the (a) resin having a structure represented by Chemical Formula (1) in the first aspect of the present invention.

Examples of the diamine that provide Y may include the same diamine as the example of the diamines of the (a) resin having a structure represented by Chemical Formula (1) in the first aspect of the present invention.

The partial structures represented by Chemical Formula (5) and a partial structure represented by Chemical Formula (6) are the partial structures of the main chain terminal of the resin having the repeating units represented by Chemical Formula (4) as the main component. X, Y, R³ and R⁴ each in Chemical Formulas (5) and (6) are the same as those in Chemical Formula (4).

W in Chemical Formula (5) and Z in Chemical Formula (6) represent the terminal structures of the resin and represent structures represented by Chemical Formula (7) and (2), respectively.

δ in Chemical Formula (7) and a in Chemical Formula (2) each independently represent a monovalent hydrocarbon group having two or more carbon atoms. δ and α each are preferably a monovalent hydrocarbon group having 2 to 10 carbon atoms. δ and α each are further preferably an aliphatic hydrocarbon group and may be any one of a linear hydrocarbon group, a branched hydrocarbon group, and a cyclic hydrocarbon group.

Examples of the hydrocarbon group include straight chain hydrocarbon groups such as an ethyl group, a n-propyl group, a n-butyl group, a n-pentyl group, a n-hexyl group, a n-heptyl group, a n-octyl group, a n-nonyl group, and a n-decyl group, branched chain hydrocarbon groups such as an isopropyl group, an isobutyl group, a sec-butyl group, a tert-butyl group, an isopentyl group, a sec-pentyl group, a tert-pentyl group, an isohexyl group, and a sec-hexyl group, and cyclic hydrocarbon groups such as a cyclopropyl group, a cyclobutyl group, a cyclopentyl group, a cyclohexyl group, a cycloheptyl group, a cyclooctyl group, a norbornyl group, and an adamantyl group.

Among these hydrocarbon groups, a monovalent branched hydrocarbon group and a cyclic hydrocarbon group having 2 to 10 carbon atoms are preferable, an isopropyl group, a cyclohexyl group, a tert-butyl group, and tert-pentyl group are more preferable, and tert-butyl group is the most preferable.

ε in Chemical Formula (7) and β and γ in Chemical Formula (2) each independently represent an oxygen atom or a sulfur atom and is preferably an oxygen atom.

When the resin containing a partial structure represented by Chemical Formula (5) is heated, W is eliminated to generate an acid anhydride group in the terminal of the resin. In addition, when the resin containing the partial structure represented by Chemical Formula (6) is heated, Z is eliminated to generate an amino group at the terminal of the resin.

Here, it will be described that the polyimide resin having a high degree of polymerization is obtained by heating the resin composition including one or more resins selected from the group consisting of (A) and (B).

(A) a resin mixture including a resin (A-1) including two or more partial structure represented by Chemical Formula (5) in a molecule and a resin (A-2) including two or more partial structure represented by Chemical Formula (6) in a molecule; and

(B) a resin including one or more partial structures represented by Chemical Formula (5) and one or more partial structures represented by Chemical Formula (6) in a molecule.

The resin (A) is a mixture of resin (A-1) that generates acid anhydride groups at two or more terminals by heating and the resin (A-2) that generates amino groups at two or more terminals by heating. Therefore, the acid anhydride group and the amino group generated at the terminal by heating are reacted and thus the resin (A-1) and the resin (A-2) alternately bond to each other to provide the polyimide resin having a high degree of polymerization.

In addition, the resin (B) generates the acid anhydride group and the amino group at different terminals from each other in the molecule by heating and thus the resin (B) is bonded with each other to provide the polyimide resin having a high degree of polymerization.

If the resin (A) contains the resin (A-1) alone or the resin (A-2) alone, either acid anhydride group or amino group is only generated even when the resin (A) is heated and thus a polyimide resin having a high degree of polymerization cannot be obtained. In addition, when the resin (B) contains either of the partial structure represented by Chemical Formula (5) alone or the partial structure represented by Chemical Formula (6) alone in the molecule, either acid anhydride group or amino group is only generated even when the resin (B) is heated and thus a polyimide resin having a high degree of polymerization cannot be obtained.

Moreover, in the resin composition including one or more resins selected from the group consisting of (A) and (B), unprotected acid anhydride groups or amino groups are not present at the terminal of the resin or the amount of these groups are small even if these groups are present. Therefore, the resin composition containing the polyamic acid according to the present invention has high viscosity stability during storage as a varnish. This is because, although the unprotected acid anhydride groups and the unprotected amino groups can react with moisture in the resin composition and oxygen in the atmosphere, respectively, these reactions are reduced in the polyamic acid resin composition according to the present invention.

The weight average molecular weight of the resin having the repeating units represented by Chemical Formula (4) as the main component measured with gel permeation chromatography in terms of polystyrene is preferably 200,000 or less, more preferably 150,000 or less, and further preferably 100,000 or less. When the weight average molecular weight is within this range, an increase in viscosity can be further reduced even at high concentration of the resin composition. In addition, the weight average molecular weight is preferably 2,000 or more, more preferably 3,000 or more, and further preferably 5,000 or more. When the weight average molecular weight is 2,000 or more, the viscosity when the resin composition is formed is not excessively lowered, and thus more favorable application properties can be retained.

The number of repetitions of structural units in Chemical Formula (4) may be in a range that satisfies the above weight average molecular weight. The number of repetitions is preferably 5 or more and more preferably 10 or more. In addition, the number of repetitions is preferably 1000 or less and more preferably 500 or less.

Subsequently, (b) the solvent used in the first aspect and the second aspect of the present invention will be described.

(b) Solvent

The resin composition in the present invention includes the (b) solvent in addition to the (a) resin having the structure represented by Chemical Formula (1) or the (a′) resin having the repeating units represented by Chemical Formula (4) as the main component and thus the resin composition can be used as a varnish. By applying such a varnish to various supports, a coating film containing the resin having the structure represented by Chemical Formula (1) can be formed on the support. Moreover, the coating film can be used as a heat resistant resin film by heating the obtained coating film to cure.

Examples of the solvent include amides such as N-methyl-2-pyrrolidone, N-ethyl-2-pyrrolidone, N,N-dimethylformamide, N,N-dimethylacetamide, 3-methoxy-N,N-dimethylpropionamide, 3-butoxy-N,N-dimethylpropionamide, N-methyl-2-dimethylpropanamide, N-ethyl-2-methylpropanamide, N-methyl-2,2-dimethylpropanamide, N-methyl-2-methylbutanamide, N,N-dimethylisobutylamide, N,N-dimethyl-2-methylbutanamide, N,N-dimethyl-2,2-dimethylpropanamide, N-ethyl-N-methyl-2-methylpropanamide, N,N-dimethyl-2-methylpentanamide, N,N-dimethyl-2,3-dimethylbutanamide, N,N-dimethyl-2-ethylbutanamide, N,N-diethyl-2-methylpropanamide, N,N-dimethyl-2,2-dimethylbutanamide, N-ethyl-N-methyl-2,2-dimethylpropanamide, N-methyl-N-propyl-2-methylpropanamide, N-methyl-N-(1-methylethyl)-2-methylpropanamide, N,N-diethyl-2,2-dimethylpropanamide, N,N-dimethyl-2,2-dimethylpentanamide, N-ethyl-N-(1-methylethyl)-2-methylpropanamide, N-methyl-N-(2-methylpropyl)-2-methylpropanamide, N-methyl-N-(1-methylethyl)-2,2-dimethylpropanamide, and N-methyl-N-(1-methylpropyl)-2-methylpropanamide, esters such as γ-butyrolactone, ethyl acetate, propylene glycol monomethyl ether acetate, and ethyl lactate, ureas such as 1,3-dimethyl-2-imidazolidinone, N,N′-dimethylpropyleneurea, and 1,1,3,3-tetramethylurea, sulfoxides such as dimethylsulfoxide and tetramethylenesulfoxide, sulfones such as dimethylsulfone and sulfolane, ketones such as acetone, methyl ethyl ketone, diisobutyl ketone, diacetone alcohol, and cyclohexanone, ethers such as tetrahydrofuran, dioxane, propylene glycol monomethyl ether, propylene glycol monoethyl ether, diethylene glycol monomethyl ether, diethylene glycol monoethyl ether, diethylene glycol ethyl methyl ether, and diethylene glycol dimethyl ether, aromatic hydrocarbons such as toluene and xylene, alcohols such as methanol, ethanol, and isopropanol (2-propanol), and water. These solvents may be used singly or in combination of two or more of them.

The preferable content of the solvent is preferably 50 parts by mass or more, more preferably 100 parts by mass or more, preferably 2000 parts by mass or less, and more preferably 1500 parts by mass or less relative to 100 parts by mass of the resin having the structure represented by Chemical Formula (1) or 100 parts by mass of the (a′) resin having the repeating units represented by Chemical Formula (4) as the main component. When the content is in the range satisfying such conditions, the composition has a viscosity suitable for application and thus the film thickness after application can be easily controlled.

The viscosity of the resin composition in the present invention is preferably 20 mPa·s to 10,000 mPa·s and more preferably 50 mPa·s to 8,000 mPa·s. When the viscosity is less than 20 mPa·s, the resin film having sufficient film thickness cannot be obtained, whereas when the viscosity is more than 10,000 mPa·s, the resin composition is difficult to apply.

Subsequently, additives used in the first aspect and the second aspect of the present invention will be described.

(Additives)

The resin composition according to the present invention may include at least one additive selected from a (c) thermal acid generator, a (d) photoacid generator, an (e) thermal crosslinking agent, an (f) compounds including a phenolic hydroxy group, a (g) adhesion improving agent, an (h) inorganic particles, and an (i) surfactant. Among them, the (c) thermal acid generator is preferably included.

The (c) thermal acid generator is a compound that generates an acid by decomposition with heat. The resin composition according to the present invention preferably includes the thermal acid generator.

When the (A) resin having the structure represented by Chemical Formula (1) or the (a′) resin having the repeating units represented by the Chemical Formula (4) as the main component is heated, the terminal structure Z and/or the terminal structures W is thermally decomposed. The thermal decomposition of the terminal structure Z and/or the terminal structure W proceeds in a temperature of 220° C. or more. Therefore, in order to obtain the polyimide resin having a high degree of polymerization from the (a) resin having the structure represented by Chemical Formula (1) or the (a′) resin having the repeating units represented by Chemical Formula (4) as the main component, usually a temperature of 220° C. or more is required.

However, in the presence of an acid, the thermal decomposition of the terminal structure Z and/or terminal structures W is prompted due to the acid that acts as a catalyst and thus the polyimide resin having a high degree of polymerization can be obtained even when the resin composition is heated at a temperature of less than 220° C. On the other hand, in the presence of the acid, hydrolysis of the polyamic acid is promoted, resulting in a decrease in the molecular weight. In other words, the resin composition including the (a) resin having the structure represented by Chemical Formula (1) or the (a′) resin having the repeating units represented Chemical Formula (4) as the main component and the acid at the same time has low storage stability.

The resin composition according to the present invention can generate the acid only in the step of thermal imidization of the polyamic acid by including the (c) thermal acid generator. This allows the resin composition to have excellent storage stability and the polyimide film having high mechanical properties such as maximum tensile stress and elongation to be obtained even when the baking temperature is low.

As such a (c) thermal acid generator, a thermal acid generator having a thermal decomposition starting temperature in a range of 100° C. or more and less than 220° C. is preferable. The lower limit of the thermal decomposition starting temperature is more preferably 110° C. or more and further preferably 120° C. or more. In addition, the upper limit of the thermal decomposition starting temperature is more preferably 200° C. or less and further preferably 150° C. or less.

When the thermal decomposition starting temperature of the (c) thermal acid generator is 100° C. or more, storage stability when the varnish is formed is improved because the (c) thermal acid generator is not usually thermally decomposed at the room temperature.

In addition, when the thermal decomposition starting temperature of the (c) thermal acid generator is less than 220° C., the polyimide film having higher mechanical strength can be obtained from the resin composition according to the present invention. In particular, when the thermal decomposition starting temperature of the (c) thermal acid generator is preferably 200° C. or less and more preferably 150° C. or less, the mechanical properties of the polyimide film are further improved.

The thermal decomposition starting temperature of the (c) thermal acid generator can be measured with differential scanning calorimetry (DSC). Generally thermal decomposition reaction is an endothermic reaction. Therefore, when the thermal acid generator is thermally decomposed, the thermal decomposition is observed as an endothermic peak in DSC. Thermal decomposition starting temperature can be defined by the temperature of the apex of the peak.

Examples of the acid generated from the (c) thermal acid generator with heat include low nucleophilicity acids such as sulfonic acids, carboxylic acids, disulfonylimides, and trisulfonylmethanes.

The (c) thermal acid generator preferably generates an acid having a pKa of 2 or less. Specifically, the thermal acid generator is preferably sulfonic acids, alkyl carboxylic acids or aryl carboxylic acids substituted with an electron withdrawing group, and disulfonylimides and trisulfonylmethanes substituted with an electron withdrawing group which generate acids. Examples of the electron withdrawing group include a halogen atom such as a fluorine atom, a haloalkyl group such as a trifluoromethyl group, a nitro group, and a cyano group.

The (c) thermal acid generator used in the present invention may be an acid generator that generates the acid by decomposition with not only heat but also light. However, in order to facilitate the handling of the resin composition according to the present invention, the (c) thermal acid generator that is not decomposed by light is preferable. The resin composition including this thermal acid generator is not necessary to be handled with shielding environment and can be handled as a non-photosensitive resin composition.

Examples of the (c) thermal acid generator not decomposed by light include, as described below, sulfonium salts and sulfonic acid esters.

Examples of the preferable sulfonium salts include a compound represented by Chemical Formula (21).

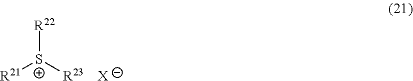

In Chemical Formula (21), R²¹ represents an aryl group and R²² and R²³ represent alkyl groups.

X⁻ represents a non-nucleophilic anion and preferable examples of X⁻ include a sulfonate anion, a carboxylate anion, a bis(alkylsulfonyl)amide anion, and a tris(alkylsulfonyl)methide anion.

The sulfonium salts represented by Chemical Formula (21) will be specifically exemplified below. The sulfonium salts, however, are not limited to these examples.

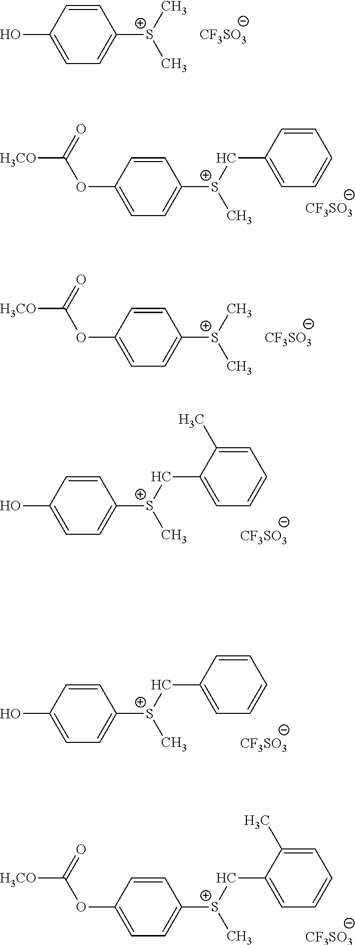

Examples of the sulfonic acid esters that can be used as the (c) thermal acid generator according to the present invention include sulfonic acid esters represented by Chemical Formula (22).

R′—SO₂—O—R″ (22)

In the chemical formula, R′ and R″ each independently are a linear, branched, or cyclic alkyl group having 1 to 10 carbon atoms that optionally has a substituent or an aryl group having 6 to 20 carbon atoms that optionally has a substituent. Examples of the substituent include a hydroxy group, a halogen atom, a cyano group, a vinyl group, an acetylene group, and a linear or cyclic alkyl group having 1 to 10 carbon atoms.

The sulfonic acid esters represented by Chemical Formula (22) will be specifically exemplified below. The sulfonic acid esters, however, are not limited to these examples.

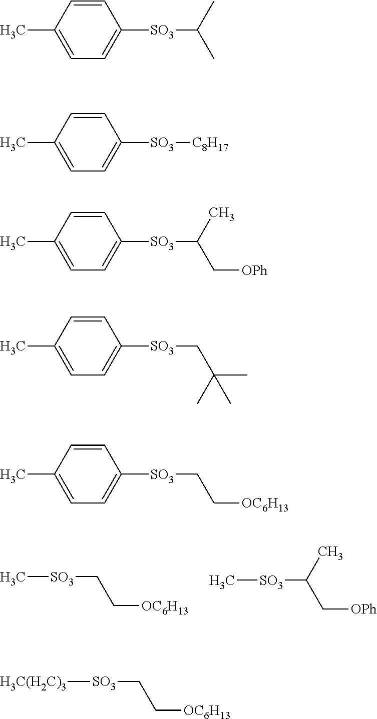

The molecular weight of the sulfonic acid ester is preferably 230 to 1000 and more preferably 230 to 800.

As the sulfonic acid ester, the compound represented by Chemical Formula (23) is further preferable from the viewpoint of heat resistance.

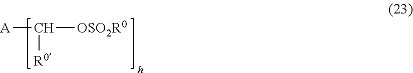

A represents an h-valent linking group. R⁰ represents an alkyl group, an aryl group, an aralkyl group, or a cyclic alkyl group. R^{0′} represents a hydrogen atom, an alkyl group, or an aralkyl group. h represents an integer of 2 to 8.

Examples of A include an alkylene group, a cycloalkylene group, an arylene group, an ether group, a carbonyl group, an ester group, an amide group, and an h-valent group formed by combining these groups.

Examples of the alkylene group include a methylene group, an ethylene group, and a propylene group.

Examples of the cycloalkylene group include a cyclohexylene group and a cyclopentylene group.

Examples of the arylene group include a 1,2-phenylene group, a 1,3-phenylene group, a 1,4-phenylene group, and a naphthylene group.

The number of carbon atoms in A is generally 1 to 15, preferably from 1 to 10, and further preferably 1 to 6.

A may further have a substituent. Examples of the substituent include an alkyl group, an aralkyl group, an aryl group, an alkoxy group, an aryloxy group, an alkylthio group, an arylthio group, an acyloxy group, and an alkoxycarbonyl group.

Examples of the alkyl group being a substituent of A include a methyl group, an ethyl group, a propyl group, a butyl group, a hexyl group, and an octyl group.

Examples of the aralkyl group being the substituent of A include a benzyl group, a toluylmethyl group, a mesitylmethyl group, and a phenethyl group.

Examples of the aryl group being the substituent of A include a phenyl group, a toluyl group, a xylyl group, a mesityl group, and a naphthyl group.

Examples of the alkoxy group being the substituent of A include a methoxy group, an ethoxy group, a linear or branched propoxy group, a linear or branched butoxy group, a linear or branched pentoxy group, a cyclopentyloxy group, and a cyclohexyloxy group.

Examples of the aryloxy group being the substituent of A include a phenoxy group, a toluoyloxy group, and a 1-naphthoxy group.

Examples of the alkylthio group being the substituent of A include a methylthio group, an ethylthio group, a linear or branched propylthio group, a cyclopentylthio group, and a cyclohexylthio group.

Examples of the arylthio group being the substituent of A include a phenylthio group, a toluylthio group, and a 1-naphthylthio group. Examples of the acyloxy group include an acetoxy group, a propanoyloxy group, and a benzoyloxy group.

Examples of the alkoxycarbonyl group being the substituent of A include a methoxycarbonyl group, an ethoxycarbonyl group, a linear or branched propoxycarbonyl group, a cyclopentyloxycarbonyl group, and a cyclohexyloxycarbonyl group.

The alkyl group of R⁰ and R^{0′} is generally an alkyl group having 1 to 20 carbon atoms, preferably an alkyl group having 1 to 15 carbon atoms, and further preferably an alkyl group having 1 to 8 carbon atoms. More specific examples may include methyl, ethyl, propyl, butyl, hexyl, and octyl.

The aralkyl group of R⁰ and R^{0′} is generally an aralkyl group having 7 to 25 carbon atoms, preferably an aralkyl group having 7 to 20 carbon atoms, and further preferably an aralkyl group having 7 to 15 carbon atoms. Specific examples may include benzyl, toluylmethyl, mesitylmethyl, and phenethyl.

The cyclic alkyl group of R⁰ is generally a cyclic alkyl group having 3 to 20 carbon atoms, preferably a cyclic alkyl group having 4 to 20 carbon atoms, and further preferably a cyclic alkyl group having 5 to 15 carbon atoms. Specific examples may include cyclopentyl, cyclohexyl, norbornyl, and a camphor group.

In Chemical Formula (23), R⁰ is preferably the alkyl group and the aryl group. R^{0′} is preferably a hydrogen atom and an alkyl group having a carbon number of 1 to 6, preferably a hydrogen atom, a methyl group, and an ethyl group, and most preferably a hydrogen atom.

h is preferably 2. h groups of R⁰ and R^{0′} may be the same as or different from each other.

Preferable specific examples of the sulfonic acid ester represented by Chemical Formula (23) include the followings. The sulfonic acid ester, however, is not limited to these examples.

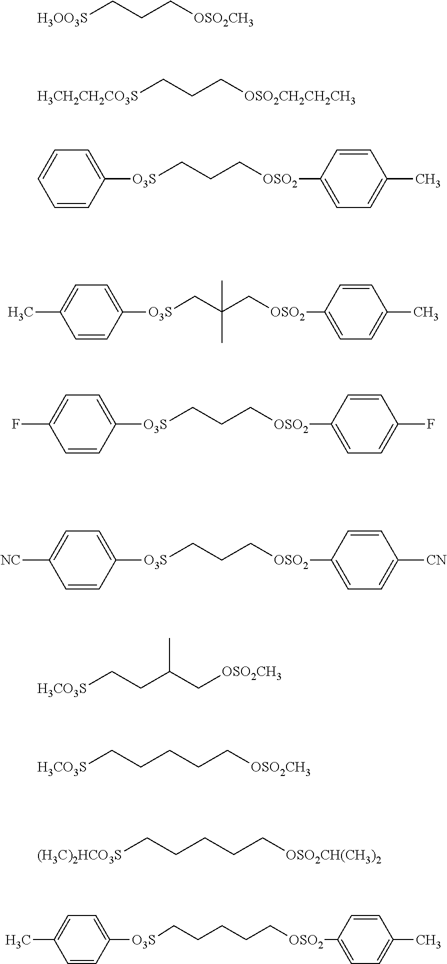

As the sulfonic acid ester, a commercially available sulfonic acid ester may be used or a sulfonic acid ester synthesized by a known method may be used. The sulfonic acid ester according to the present invention can be synthesized, for example, by reacting sulfonyl chloride or sulfonic anhydride with corresponding polyhydric alcohol under basic conditions.

In the present invention, the preferable content of the (c) thermal acid generator is preferably 0.1 part by mass or more, more preferably 1 part by mass or more, preferably 20 parts by mass or less, and more preferably 10 parts by mass or less relative to 100 parts by mass of the resin having the structure represented by Chemical Formula (1) or 100 parts by mass of the (a′) the resin having the repeating units represented by Chemical Formula (4) as the main component. When the content is 0.1 part by mass or more, the polyimide film having high mechanical strength can be obtained from the resin composition after heating. In addition, when the content is 20 parts by mass or less, the thermal decomposition product of thermal acid generator is less likely to remain in the obtained polyimide film and thus gas released from the polyimide film can be reduced from the polyimide film.

(d) Photoacid Generator

The resin composition according to the present invention may be a photosensitive resin composition by including the (d) photoacid generator. By including the (d) photoacid generator, an acid is generated at a light irradiation portion to increase solubility in an alkali aqueous solution of the light irradiation portion and thus a positive type relief pattern formed by dissolving the light irradiation part can be obtained. In addition, in the resin composition according to the present invention, the acid generated in the light irradiation part promotes the crosslinking reaction of an epoxy compound and an (e) thermal crosslinking agent by including the (d) photoacid generator and the epoxy compound or the (e) thermal crosslinking agent described below and thus a negative type relief pattern in which the light irradiation part is insolubilized can be obtained.

Examples of the (d) photoacid generator include quinonediazide compounds, sulfonium salts, phosphonium salts, diazonium salts, and iodonium salts. Two or more of these compounds may be included and a high sensitive photosensitive resin composition can be obtained.

Examples of the quinonediazide compound include a compound in which sulfonic acid of quinonediazide is bonded to a polyhydroxy compound in the form of ester, a compound in which sulfonic acid of quinonediazide is bonded to a polyamino compound in the form of amide, and a compound in which sulfonic acid of quinonediazide is bonded to a polyhydroxyamino compound in the form of ester and/or sulfonamide. 50% by mol or more of the total functional groups of these polyhydroxy compounds and polyamino compounds are preferably substituted with quinonediazide.

In the present invention, both 5-naphthoquinone diazide sulfonyl group and 4-naphthoquinone diazide sulfonyl group are preferably used as quinonediazide. A 4-naphthoquinone diazide sulfonyl ester compound has an absorption in the i-line region of a mercury lamp and is suitable for i-line exposure. A 5-naphthoquinone diazide sulfonyl ester compound has absorption reaching to the g-line region of a mercury lamp and is suitable for g-line exposure. In the present invention, the 4-naphthoquinone diazide sulfonyl ester compound and the 5-naphthoquinone diazide sulfonyl ester compound are preferably selected depending on the wavelength of exposure. In addition, a naphthoquinone diazide sulfonyl ester compound including both 4-naphthoquinone diazide sulfonyl group and 5-naphthoquinone diazide sulfonyl group in the same molecule may be included or both 4-naphthoquinone diazide sulfonyl ester compound and 5-naphthoquinone diazide sulfonyl ester compound may be included in the same resin composition.

Among the (D) photoacid generators, sulfonium salts, phosphonium salts, diazonium salts are preferable in order to appropriately stabilize the acid component generated by exposure. Among them, the sulfonium salts are preferable. Further, a sensitizer and the like may be included, if necessary.

In the present invention, the content of the (d) photoacid generator is preferably 0.01 part by mass to 50 parts by mass relative to 100 parts by mass of the resin having the structure represented by Chemical Formula (1) or 100 parts by mass of the (a′) resin having the repeating units represented by Chemical Formula (4) as the main component from the viewpoint of achieving high sensitivity. Among them, the quinonediazide compound is preferably included in 3 parts by mass to 40 parts by mass. In addition, the total amount of the sulfonium salts, the phosphonium salts, and the diazonium salt is preferably 0.5 part by mass to 20 parts by mass.

(e) Thermal Crosslinking Agent

The resin composition in the present invention may include a thermal crosslinking agent (e-1) represented by Chemical Formula (31) or a thermal crosslinking agent (e-2) represented by Chemical Formula (32) (hereinafter these agents are referred to as an (e) thermal crosslinking agent) together. These thermal crosslinking agents can improve the chemical resistance and hardness of the obtained heat resistant resin film by crosslinking the heat resistant resin or its precursor and other additive components.

Thermal crosslinking agent (e-1) includes a structure represented by Chemical Formula (31).

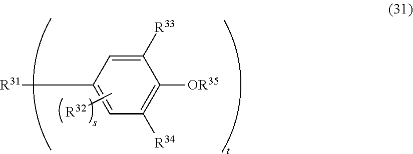

In Chemical Formula (31), R³¹ represents a divalent to tetravalent linking group. R³² represents a monovalent hydrocarbon group having 1 to 20 carbon atoms, Cl, Br, I, or F. R³³ and R³⁴ each independently represent CH₂OR³⁶ (R³⁶ is hydrogen atom or a monovalent hydrocarbon group having 1 to 6 carbon atoms). R³⁵ represents a hydrogen atom, a methyl group, or an ethyl group. s is an integer of 0 to 2 and t is an integer of 2 to 4. When a plurality of R³²s exist, R³²s are the same as or different from each other. When a plurality of R³³s and R³⁴s exist, R³³s and R³⁴s may be the same as or different from each other. When a plurality of R³⁵s exist, R³⁵s may be the same as or different from each other. Examples of the linking group R³¹ are illustrated below.

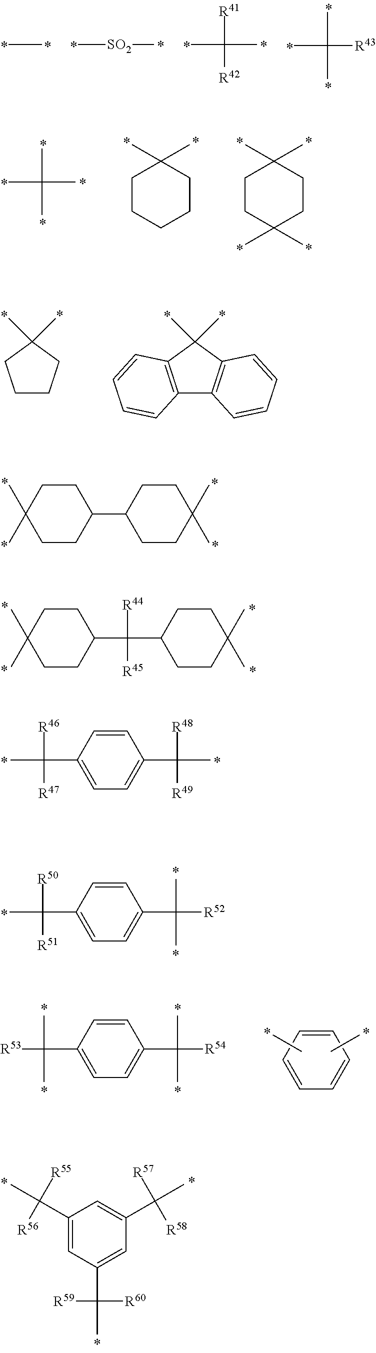

In Chemical Formula (31), R⁴¹ and R³⁴ represent CH₂OR³⁶ being a thermally crosslinkable group. R³⁶ is preferably a monovalent hydrocarbon group having 1 to 4 carbon atoms and more preferably a methyl group or an ethyl group, from the viewpoint of leaving moderate reactivity to the thermal crosslinking agent of Chemical Formula (31) and providing excellent storage stability.

Preferable examples of the thermal crosslinking agent including a structure represented by Chemical Formula (31) are illustrated below.

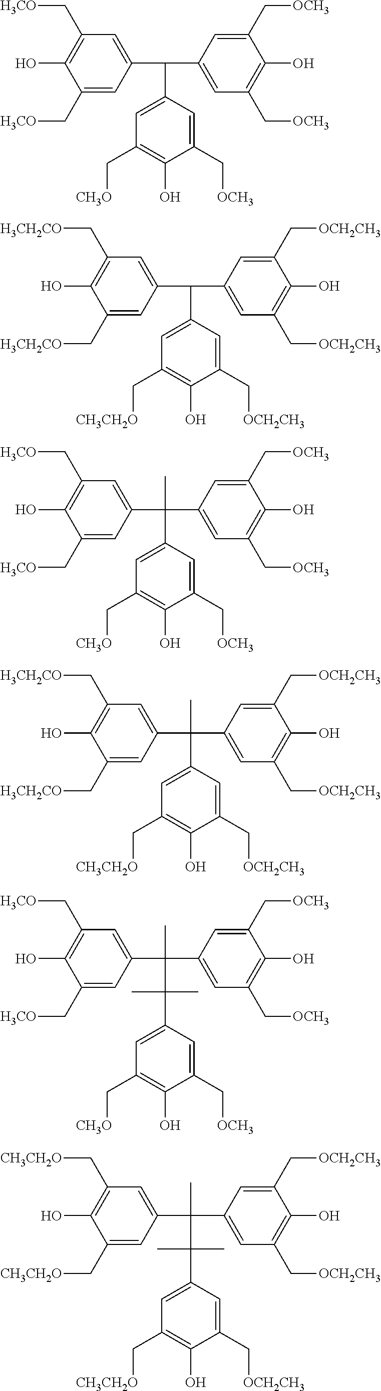

The thermal crosslinking agent (e-2) includes a structure represented by Chemical Formula (32).

*—N(CH₂OR³⁷)_{U}(H)_{V} (32)

In Chemical Formula (32), R³⁷ represents a hydrogen atom or a monovalent hydrocarbon group having 1 to 6 carbon atoms. u represents 1 or 2 and v represents 0 or 1. Here, u+v is 1 or 2. * indicates that the nitrogen atom in Chemical Formula (32) is bonded to another atom.

In Chemical Formula (32), R³⁷ is preferably a monovalent hydrocarbon group having 1 to 4 carbon atoms. In addition, R³⁷ is preferably a methyl group or an ethyl group and the number of (CH₂OR³⁷) groups in the compound is 8 or less, from the viewpoint of the stability of the compound and the storage stability of the photosensitive resin composition.

Preferable examples of the thermal crosslinking agent including a group represented by Chemical Formula (32) are illustrated below.

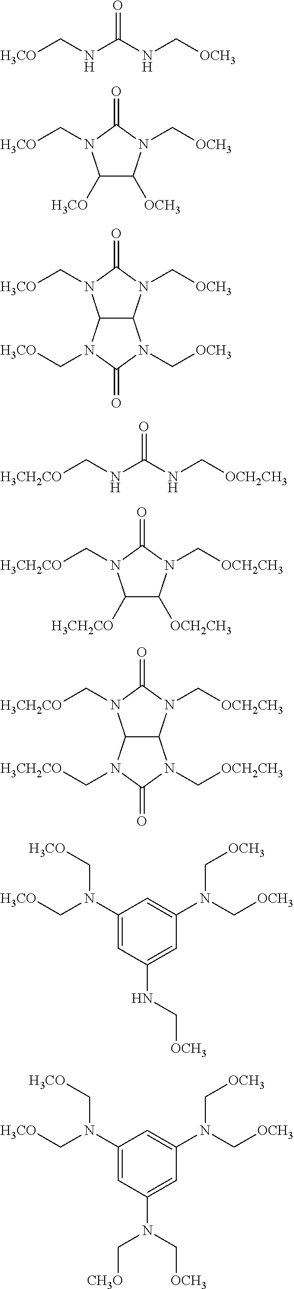

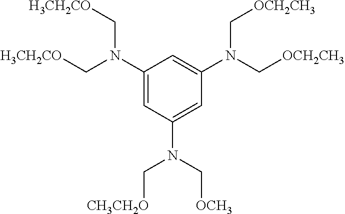

The content of the (e) thermal crosslinking agent is preferably 10 parts by mass or more and 100 parts by mass 100 parts by mass of the (a′) resin having the repeating units represented by Chemical Formula (4) as the main component. When the content of the (e) thermal crosslinking agent is 10 parts by mass or more and 100 pats by mass or less, the obtained heat resistant resin film has high strength and the resin composition has excellent storage stability.

(f) Compound Containing Phenolic Hydroxy Groups

In order to compensate for the alkali developability of the photosensitive resin composition, the resin composition may include a compound containing a phenolic hydroxy group. Examples of the compound containing a phenolic hydroxy group include products manufactured by Honshu Chemical Industry Co., Ltd. having the following trade names (Bis-Z, BisOC-Z, BisOPP-Z, BisP-CP, Bis26X-Z, BisOTBP-Z, BisOCHP-Z, BisOCR-CP, BisP-MZ, BisP-EZ, Bis26X-CP, BisP-PZ, BisP-IPZ, BisCR-IPZ, BisOCP-IPZ, BisOIPP-CP, Bis26X-IPZ, BisOTBP-CP, TekP-4HBPA (tetrakis-P-DO-BPA), TrisP-HAP, TrisP-PA, TrisP-PHBA, TrisP-SA, TrisOCR-PA, BisOFP-Z, BisRS-2P, BisPG-26X, BisRS-3P, BisOC-OCHP, BisPC-OCHP, Bis25X-OCHP, Bis26X-OCHP, BisOCHP-OC, Bis236T-OCHP, methylene tris-FR-CR, BisRS-26X, and BisRS-OCHP), products manufactured by Asahi Organic Chemicals Industry Co., Ltd. having the following trade names (BIR-OC, BIP-PC, BIR-PC, BIR-PTBP, BIR-PCHP, BIP-BIOC-F, 4PC, BIR-BIPC-F, and TEP-BIP-a), 1,4-dihydroxynaphthalene, 1,5-dihydroxynaphthalene, 1,6-dihydroxynaphthalene, 1,7-dihydroxynaphthalene, 2,3-dihydroxynaphthalene, 2,6-dihydroxynaphthalene, 2,7-dihydroxynaphthalene, 2,4-dihydroxyquinoline, 2,6-dihydroxyquinoline, 2,3-dihydroxyquinoxaline, anthracene-1,2,10-triol, anthracene-1,8,9-triol, and 8-quinolinol. By containing the compounds containing the phenolic hydroxy group, the obtained photosensitive resin composition hardly dissolves in an alkaline developing liquid before exposure to light and easily dissolves in the alkaline developing liquid after the photosensitive resin is exposed to light. Consequently, film loss caused by development is small and the photosensitive resin composition can be easily developed in a small amount of time. Therefore, the sensitivity is likely to increase.

The content of such a compound containing phenolic hydroxy groups is preferably 3 parts by mass or more and 40 parts by mass or less relative to 100 parts by mass of the resin having the structure represented by Chemical Formula (1) or 100 parts by mass of the (a′) resin having the repeating units represented by Chemical Formula (4) as the main component.

(g) Adhesion Improving Agent

The resin composition according to the present invention may include a (g) adhesion improving agent. Examples of the (g) adhesion improving agent include silane coupling agents such as vinyltrimethoxysilane, vinyltriethoxysilane, epoxycyclohexylethyltrimethoxysilane, 3-glycidoxypropyltrimethoxysilane, 3-glycidoxypropyltriethoxysilane, p-styryltrimethoxysilane, 3-aminopropyltrimethoxysilane, 3-aminopropyltriethoxysilane, and N-phenyl-3-aminopropyltrimethoxysilane, titanium chelating agents, and aluminum chelating agents. In addition to these compounds, alkoxysilane-containing aromatic amine compounds and alkoxysilane-containing aromatic amide compounds as illustrated below are included.

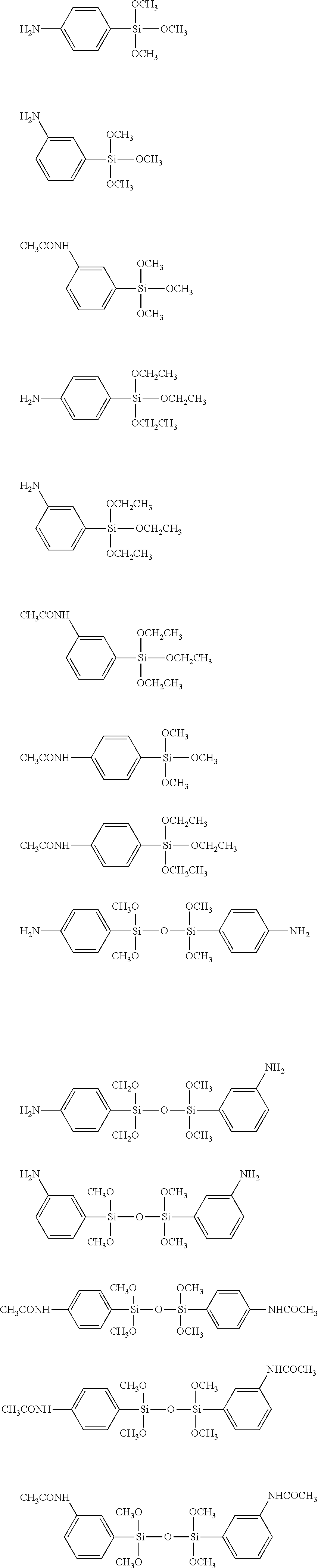

In addition, a compound obtained by reacting an aromatic amine compound and an alkoxy group-containing silicon compound may be used. Examples of such a compound include a compound obtained by reacting an aromatic amine compound with an alkoxysilane compound containing a reactive group with an amino group such as an epoxy group and a chloromethyl group. Two or more adhesion improving agent described above may be included. By containing these adhesion improving agents, the adhesion to the base substrate such as a silicon wafer, ITO, SiO₂, and silicon nitride can be improved when the photosensitive resin film is developed. In addition, resistance to oxygen plasma and UV ozone treatment used in washing can be improved by improving the adhesion between the heat resistant resin film and the base substrate. The content of the adhesion improving agent is preferably 0.01 part by mass to 10 parts by mass relative to 100 parts by mass of the resin having the structure represented by Chemical Formula (1) or 100 parts by mass of the (a′) resin having the repeating units represented by Chemical Formula (4) as the main component.

(h) Inorganic Particles

The resin composition according to the present invention may include inorganic particles in order to improve heat resistance. Examples of the inorganic particles used for such purposes include metal inorganic particles such as platinum, gold, palladium, silver, copper, nickel, zinc, aluminum, iron, cobalt, rhodium, ruthenium, tin, lead, bismuth, and tungsten and metal oxide inorganic particles such as silicon oxide (silica), titanium oxide, aluminum oxide, zinc oxide, tin oxide, tungsten oxide, zirconium oxide, calcium carbonate, and barium sulfate. The shape of the inorganic particles is not particularly limited and examples of the shape include a spherical shape, an elliptical shape, a flat shape, a rod-like shape, and a fibrous shape. In addition, in order to prevent an increase in the surface roughness of the heat resistant resin film including the inorganic particles, the average particle diameter of the inorganic particles is preferably 1 nm or more and 100 nm or less, more preferably 1 nm or more and 50 nm or less, and further preferably to 1 nm or more and 30 nm or less.

The content of the inorganic particles is preferably 3 parts by mass or more, more preferably 5 parts by mass or more, further preferably 10 parts by mass or more, preferably 100 parts by mass or less, more preferably 80 parts by mass or less, and further preferably 50 parts by mass or less relative to 100 parts by mass of the (a) resin having the structure represented by Chemical Formula (1) or 100 parts by mass of the (a′) resin having the repeating units represented by Chemical Formula (4) as the main component. When the content of the inorganic particles is 3 parts by mass or more, heat resistance is sufficiently improved, whereas when the content is 100 parts by mass or less, the toughness of the heat resistant resin film is less likely to decrease.

(i) Surfactant

In order to improve application properties, the resin composition according to the present invention preferably includes an (i) surfactant. Examples of the (i) surfactant include fluorochemical surfactants such as “Fluorad” (registered trademark) manufactured by Sumitomo 3M Co., Ltd., “Megafac” (registered trademark), manufactured by DIC Corporation, and “Surufuron” (registered trademark) manufactured by Asahi Glass Co., Ltd., organosiloxane surfactants such as KP341 manufactured by Shin-Etsu Chemical Co., Ltd., DBE manufactured by Chisso Co., Ltd., and “POLYFLOW” (registered trademark) and “Granol” (registered trademark) manufactured by Kyoeisha Chemical Co., and BYK manufactured by BYK-Chemie GmbH, and acrylic polymer surfactant such as POLYFLOW manufactured by Kyoeisha Chemical Co., Ltd. The surfactant is preferably contained in 0.01 part by mass to 10 parts by mass relative to 100 parts by mass of the (a) resin having the structure represented by Chemical Formula (1) or 100 parts by mass of the (a′) resin having the repeating units represented by Chemical Formula (4) as the main component.

(Method for producing resin composition) Subsequently, a method for producing resin composition according to the first aspect of the present invention will be described.

For example, a varnish being one of the embodiments of the resin composition according to the present invention can be obtained by dissolving the (a) resin having the structure represented by Chemical Formula (1) and, if necessary, the (c) thermal acid generator, the (d) photoacid generator, the (e) thermal crosslinking agent, the (f) compounds including a phenolic hydroxy group, the (g) adhesion improving agent, the (h) inorganic particles, and the (i) surfactant in the (b) solvent. As the dissolution method, stirring and heating are exemplified. When the (d) photoacid generator is included, the heating temperature is preferably determined within a range not impairing the performance as the photosensitive resin composition. Usually, the temperature is room temperature to 80° C. In addition, dissolution order of each of the components is not particularly limited. For example, a method for sequentially dissolving the components from a compound having low solubility may be included. In addition, for the component such as the (i) surfactant that tends to generate air bubbles at the time of dissolving by stirring, dissolving failure of other components due to bubble generation can be prevented by finally adding the surfactant after dissolving the other components.

The resin having the structure represented by Chemical Formula (1) is produced by the two methods described below.

The first method for producing the resin includes

(A) a step of producing a compound represented by Chemical Formula (41) by gradually adding a solution in which a terminal amino group blocking agent that is reactive with an amino group of a diamine compound is dissolved in a reaction solvent in 20% by mass or less over a time of 10 minutes or more;

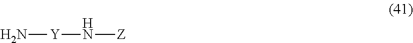

in Chemical Formula (41), Y represents a divalent diamine residue having two or more carbon atoms; Z represents a structure represented by Chemical Formula (2);

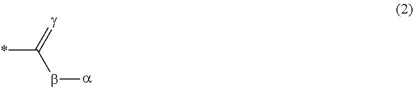

in Chemical Formula (2), a represents a monovalent hydrocarbon group having 2 or more carbon atoms and β and γ each independently represent an oxygen atom or a sulfur atom; * indicates a bonding point of Z in Chemical Formula (41); and

(B) a step of reacting the compound represented by Chemical Formula (41), a tetracarboxylic acid, and the residual diamine compound having not reacted with the terminal amino group blocking agent in the (A) step;

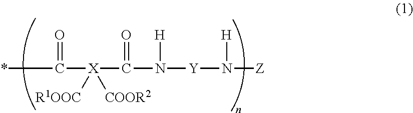

in Chemical Formula (1), X represents a tetravalent tetracarboxylic acid residue having two or more carbon atoms and Y represents a divalent diamine residue having two or more carbon atoms; Z represents a structure represented by Chemical Formula (2); n represents a positive integer; R¹ and R² each independently represent a hydrogen atom, a hydrocarbon group having 1 to 10 carbon atoms or an alkylsilyl group having 1 to 10 carbon atoms, an alkali metal ion, an ammonium ion, an imidazolium ion, or a pyridinium ion. * indicates that the carbon atom is bonded to another atom.

In the first production method, in the (A) step of the first stage, only one amino group in the two amino groups that the diamine compound has is reacted with the terminal amino group blocking agent. Therefore, the following three operations described below are preferably carried out in the (A) step of the first stage.

The first operation is an operation in which the number of moles of the diamine compound is set equal to or more than the number of moles of the terminal amino group blocking agent. The number of moles of the diamine compound is preferably equal to or more than twice the number of moles of the terminal amino group blocking agent, more preferably equal to or more than five times the number of moles, and further preferably equal to or more than ten times the number of moles. Here, the excess diamine compound to the terminal amino group blocking agent remains unreacted in the (A) step of the first stage and is reacted with a tetracarboxylic acid in the (B) step of the second stage.

The second operation is an operation in which the terminal amino group blocking agent is gradually added over a time of 10 minutes or more in a state where the diamine compound is dissolved in a suitable reaction solvent. The time is more preferably 20 minutes or more and further preferably 30 minutes or more. Here, the method for adding the terminal amino group blocking agent may be continuous or intermittent. In other words, either a method of adding the terminal amino group blocking agent to the reaction system at a constant rate using a dropping funnel or a method of separately adding the terminal amino group blocking agent at appropriate intervals is preferably employed.

The third operation is an operation in which the terminal amino group blocking agent is previously dissolved in the reaction solvent to use in the second operation. The concentration when the terminal amino group blocking agent is dissolved is 5% by mass to 20% by mass. The concentration is more preferably 15% by mass or less and further preferably 10% by mass or less.

In the production of the resin, by carrying out the above operations, the content of the compound represented by Chemical Formula (3) in the resin composition according to the present invention can fall within the range according to the present invention.

The second method for producing the resin includes (C) a step of producing a resin having a structure represented by Chemical Formula (42) by reacting a diamine compound and a tetracarboxylic acid; and

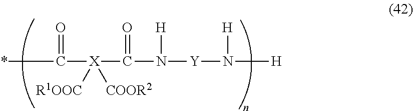

In Chemical Formula (42), X represents a tetravalent tetracarboxylic acid residue having two or more carbon atoms and Y represents a divalent diamine residue having two or more carbon atoms. n represents a positive integer. R¹ and R² each independently represent a hydrogen atom, a hydrocarbon group having 1 to 10 carbon atoms or an alkylsilyl group having 1 to 10 carbon atoms, an alkali metal ion, an ammonium ion, an imidazolium ion, or a pyridinium ion. * indicates that the carbon atom is bonded to another atom.

(D) a step of producing a resin having a structure represented by Chemical Formula (1) by reacting the resin having the structure represented by Chemical Formula (42) and a terminal amino group blocking agent that is reactive with the terminal amino group of the resin having the structure represented by Chemical Formula (42).

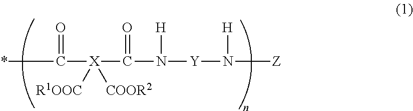

In Chemical Formula (1), X represents a tetravalent tetracarboxylic acid residue having two or more carbon atoms and Y represents a divalent diamine residue having two or more carbon atoms. Z represents a structure represented by Chemical Formula (2). n represents a positive integer. R¹ and R² each independently represents a hydrogen atom, a hydrocarbon group having 1 to 10 carbon atoms, an alkylsilyl group having 1 to 10 carbon atoms, an alkali metal ion, an ammonium ion, an imidazolium ion, or a pyridinium ion. * indicates that the carbon atom is bonded to another atom.

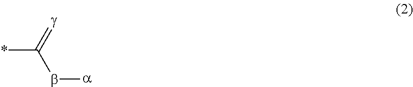

In Chemical Formula (2), a represents a monovalent hydrocarbon group having 2 or more carbon atoms and β and γ each independently represent an oxygen atom or a sulfur atom. * indicates the bonding point of Z in Chemical Formula (1).

In the second production method, production of a compound represented by Chemical Formula (3) can be reduced because the diamine compound and the terminal amino group blocking agent are not directly reacted.

In the step (C) of the first stage, in order to produce the resin having the structure represented by Chemical Formula (42), the number of moles of the diamine compound is determined to be 1.01 times or more the number of moles of the tetracarboxylic acid, more preferably 1.05 times or more, more preferably 1.1 times or more the number of moles, and further preferably 1.2 times or more. When the number of moles of the diamine compound is less than 1.01 times, the resin having the structure of Chemical Formula (42) is hardly obtained because the possibility where the diamine compound is positioned at the terminal of the resin is decreased.

In addition, the number of moles of the diamine compound is preferably 2.0 times or less the number of moles of the tetracarboxylic acid, more preferably 1.8 times or less, and further preferably 1.5 times or less. When the number of moles of the diamine compound is more than 2.0 times, the unreacted diamine compound remains after completion of the reaction in the first stage and the compound represented by Chemical Formula (3) may be produced in the step (C) being the second stage.

In the (D) step being the second stage, the method described in the first production method may be employed as the operation of adding the terminal amino group blocking agent. In other words, the terminal amino group blocking agent may be added over time or the terminal amino group blocking agent may be dissolved in an adequate reaction solvent and the resultant solution may be added. When the diamine compound remains in the reaction in the first stage, the content of the compound represented by Chemical Formula (3) in the resin composition can fall within the range according to the present invention by these methods.

Here, as described below, the number of moles of the diamine compound to be used and the number of moles of the tetracarboxylic acid to be used are preferably equal. Consequently, after the (D) step being the second stage, the number of moles of the diamine compound and the number of moles of the tetracarboxylic acid is preferably equalize by adding the tetracarboxylic acid.

Moreover, the resin having the structure represented by Chemical Formula (1) may be produced by employing both of the first production method and the second production method.

As the terminal amino group blocking agent, dicarbonate esters and dithiocarbonate esters are preferably used. Among them, dialkyl dicarbonate esters and dialkyl dithiocarbonate ester are preferable. Dialkyl dicarbonate esters are more preferable. Specific examples include diethyl dicarbonate, diisopropyl dicarbonate, dicyclohexyl dicarbonate, di-tert-butyl dicarbonate, and di-tert-pentyl dicarbonate. Among them, di-tert-butyl dicarbonate is the most preferable dialkyl dicarbonate ester.

Here, in the first production method and the second production method, the corresponding dianhydrides, active esters, and active amides may be also used as the tetracarboxylic acid. In addition, as the diamine compound, the corresponding trimethylsilylated diamine and the like may be also used. In addition, the carboxy group in the obtained resin may form a salt of an alkali metal ion, an ammonium ion, and an imidazolium ion or may form esters of a hydrocarbon group having 1 to 10 carbon atoms or an alkylsilyl group having 1 to 10 carbon atoms.

In addition, in the first production method and the second production method, the number of moles of the diamine compound to be used and the number of moles of the tetracarboxylic acid to be used are preferably equal. When the numbers of moles are equal, the resin film having high mechanical strength is likely to be obtained from the resin composition.

In the first production method and the second production method, examples of the reaction solvent include amides such as N-methyl-2-pyrrolidone, N-ethyl-2-pyrrolidone, N,N-dimethylformamide, N,N-dimethylacetamide, 3-methoxy-N,N-dimethylpropionamide, 3-butoxy-N,N-dimethylpropionamide, N-methyl-2-dimethylpropanamide, N-ethyl-2-methylpropanamide, N-methyl-2,2-dimethylpropanamide, N-methyl-2-methylbutanamide, N,N-dimethylisobutylamide, N,N-dimethyl-2-methylbutanamide, N,N-dimethyl-2,2-dimethylpropanamide, N-ethyl-N-methyl-2-methylpropanamide, N,N-dimethyl-2-methylpentanamide, N,N-dimethyl-2,3-dimethylbutanamide, N,N-dimethyl-2-ethylbutanamide, N,N-diethyl-2-methylpropanamide, N,N-dimethyl-2,2-dimethylbutanamide, N-ethyl-N-methyl-2,2-dimethylpropanamide, N-methyl-N-propyl-2-methylpropanamide, N-methyl-N-(1-methylethyl)-2-methylpropanamide, N,N-diethyl-2,2-dimethylpropanamide, N,N-dimethyl-2,2-dimethylpentanamide, N-ethyl-N-(1-methylethyl)-2-methylpropanamide, N-methyl-N-(2-methypropyl)-2-methylpropanamide, N-methyl-N-(1-methylethyl)-2,2-dimethylpropanamide, and N-methyl-N-(l-methylpropyl)-2-methylpropanamide, esters such as γ-butyrolactone, ethyl acetate, propylene glycol monomethyl ether acetate, and ethyl lactate, ureas such as 1,3-dimethyl-2-imidazolidinone, N,N′-dimethylpropyleneurea, and 1,1,3,3-tetramethylurea, sulfoxides such as dimethylsulfoxide and tetramethylenesulfoxide, sulfones such as dimethylsulfone and sulfolane, ketones such as acetone, methyl ethyl ketone, diisobutyl ketone, diacetone alcohol, and cyclohexanone, ethers such as tetrahydrofuran, dioxane, propylene glycol monomethyl ether, propylene glycol monoethyl ether, diethylene glycol monomethyl ether, diethylene glycol monoethyl ether, diethylene glycol ethyl methyl ether, and diethylene glycol dimethyl ether, aromatic hydrocarbons such as toluene and xylene, alcohols such as methanol, ethanol, and isopropanol (2-propanol), and water. These solvents may be used singly or in combination of two or more of them.

In addition, the target resin composition can be obtained without isolating the resin by using the same (b) solvent used in the resin composition for the reaction solvent or by adding the (b) solvent after completion of the reaction.

The obtained resin composition is preferably filtered using a filtration filter to remove particles. As the filter pore diameter, 10 μm, 3 μm, 1 μm, 0.5 μm, 0.2 μm, 0.1 μm, 0.07 μm, and 0.05 μm are exemplified. The filter pore diameter, however, is not limited to these examples. As the material of the filtration filter, polypropylene (PP), polyethylene (PE), nylon (NY), and polytetrafluoroethylene (PTFE) are exemplified and polyethylene and nylon are preferable. The number of particles in the resin composition (particle size 1 μm or more) is preferably 100 particles/mL or less. When number of particles is more than 100 particles/mL, the mechanical properties of the heat resistant resin film obtained from the resin composition deteriorates.

Subsequently, the method for producing the resin composition according to the second aspect of the present invention will be described.

For example, a varnish being one of the embodiments of the resin composition according to the present invention can be obtained by dissolving the (a′) resin composition resin including a resin having a repeating unit represented by Chemical Formula (4A) as the main component and, if necessary, the (c) thermal acid generator, the (d) photoacid generator, the (e) thermal crosslinking agent, the (f) compounds including a phenolic hydroxy group, the (g) adhesion improving agent, the (h) inorganic particles, and the (i) surfactant in the (b) solvent. As the dissolution method, stirring and heating are exemplified. When the (d) photoacid generator is included, the heating temperature is preferably determined within a range not impairing the performance as the photosensitive resin composition. Usually, the temperature is room temperature to 80° C. In addition, dissolution order of each of the components is not particularly limited. For example, a method for sequentially dissolving the components from a compound having low solubility may be included. In addition, for the component such as the (i) surfactant that tends to generate air bubbles at the time of dissolving by stirring, dissolving failure of other components due to bubble generation can be prevented by finally adding the surfactant after dissolving the other components.

The resin having the repeating units represented by Chemical Formula (4A) as the main component is produced by the two methods described below.

The first method for producing the resin includes (E) a step of producing a compound represented by Chemical Formula (41) by reacting a diamine compound and a terminal amino group blocking agent that is reactive with the amino group of the diamine compound;

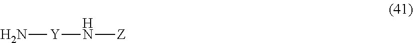

In Chemical Formula (41), Y represents a divalent diamine residue having 2 or more carbon atoms. Z represents a structure represented by Chemical Formula (2).

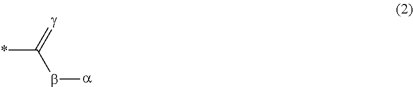

In Chemical Formula (2), a represents a monovalent hydrocarbon group having 2 or more carbon atoms and β and γ each independently represent an oxygen atom or a sulfur atom. * indicates the bonding point of Z in Chemical Formula (41).

(F) a step of producing one or more resins selected from the group consisting of the following (A′) and (B′) by reacting the compound represented by Chemical Formula (41), a tetracarboxylic dianhydride, and the residual diamine compound having not reacted with the terminal amino group blocking agent in the (E) step; and

(A′) a resin mixture including a resin (A′-1) including two or more partial structures represented by Chemical Formula (52) in a molecule and a (A′-2) resin including two or more partial structures represented by Chemical Formula (6A) in a molecule

(B′) a resin including one or more partial structures represented by Chemical Formula (52) and one or more partial structures represented by Chemical Formula (6A) in a molecule

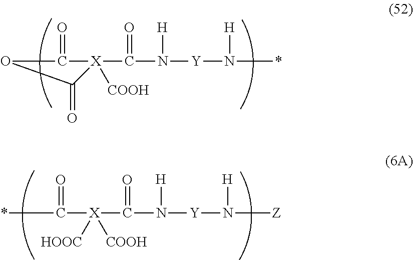

In Chemical Formulas (52) and (6A), X represents a tetravalent tetracarboxylic acid residue having two or more carbon atoms and Y represents a divalent diamine residue having two or more carbon atoms. Z represents a structure represented by Chemical Formula (2). In Chemical Formulas (52) and (6A), * indicates that the nitrogen/carbon atom is bonded to another atom.

(G) a step of producing a resin having a structure represented by Chemical Formula (5A) by reacting a terminal carbonyl group blocking agent that is reactive with the partial structure represented by Chemical Formula (52).

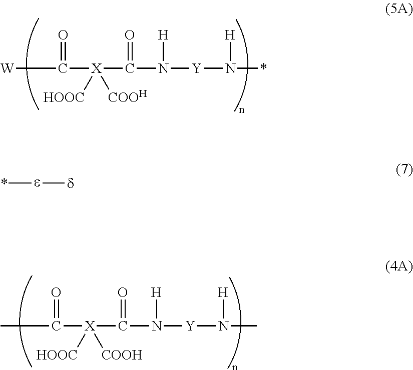

In Chemical Formulas (4A) and (5A), X represents a tetravalent tetracarboxylic acid residue having two or more carbon atoms and Y represents a divalent diamine residue having two or more carbon atoms. In Chemical Formula (5A), W represents a structure represented by Chemical Formula (7). In Chemical Formula (5A), * indicates that the nitrogen atom is bonded to another atom. δ in Chemical Formula (7) represents a monovalent hydrocarbon group having two or more carbon atoms. ε in Chemical Formula (7) represents an oxygen atom or a sulfur atom. * in Chemical Formula (7) indicates the bonding point of W in Chemical Formula (5A).

In the first production method, in the (E) step of the first stage, only one amino group in the two amino groups that the diamine compound has is reacted with the terminal amino group blocking agent. Therefore, in the (E) step of the first stage, the number of moles of the diamine compound is preferably set equal to or more than the number of moles of the terminal amino group blocking agent. The number of moles of diamine compounds is preferably equal to or more than twice the number of moles of the terminal amino group blocking agent, more preferably equal to or more than five times the number of moles, and further preferably equal to or more than ten times the number of moles.

Here, the excess diamine compound to the terminal amino group blocking agent remains unreacted in the (E) step of the first stage and is reacted with a tetracarboxylic acid in the (F) step of the second stage.

In the (G) step of the third stage, the number of moles of the terminal carbonyl group blocking agent is preferably one time to two times the number of moles of the terminal amino group blocking agent used in the (E) step of the first stage. When the number of moles of the terminal carbonyl group blocking agent is one time or more, unprotected acid anhydride groups are less likely to be generated at the terminal of the resin. When the number of moles of the terminal carbonyl group blocking agent is two times or less, an increase in the amount of unreacted terminal carbonyl group blocking agent can be prevented.

The second method for producing the resin includes

(H) a step of producing a compound represented by Chemical Formula (53) by reacting a tetracarboxylic dianhydride and a terminal carbonyl group blocking agent;

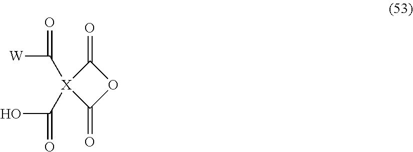

in Chemical Formula (53), X represents a tetravalent tetracarboxylic acid residue having two or more carbon atoms. W represents a structure represented by Chemical Formula (7);

*-ε-δ (7)

δ in Chemical Formula (7) represents a monovalent hydrocarbon group having two or more carbon atoms and ε represents an oxygen atom or a sulfur atom. * in Chemical Formula (7) indicates the bonding point of W in Chemical Formula (53);

(I) a step of producing one or more resins selected from the group consisting of the following (A″) and (B″) by reacting the compound represented by Chemical Formula (53), a diamine compound, and the residual tetracarboxylic dianhydride having not reacted with the terminal carbonyl group blocking agent in the (H) step;

(A″) a resin mixture including a resin (A″-1) including two or more partial structure represented by Chemical Formula (54) in a molecule and a resin (A″-2) including two or more partial structures represented by Chemical Formula (5A) in a molecule;

(B″) a resin including one or more partial structures represented by Chemical Formula (54) and one or more partial structures represented by Chemical Formula (5A) in a molecule;

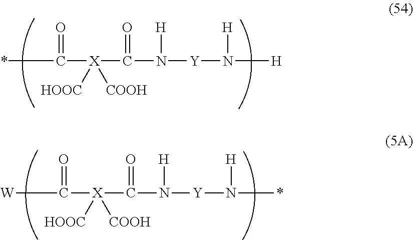

in Chemical Formulas (54) and (5A), X represents a tetravalent tetracarboxylic acid residue having two or more carbon atoms and Y represents a divalent diamine residue having two or more carbon atoms; W represents a structure represented by Chemical Formula (7); in Chemical Formulas (54) and (5A), * indicates that the carbon/nitrogen atom is bonded to another atom; and

(J) a step of producing a resin having a structure represented by Chemical Formula (6A) by reacting the partial structure represented by Chemical Formula (54) with the terminal amino group blocking agent;

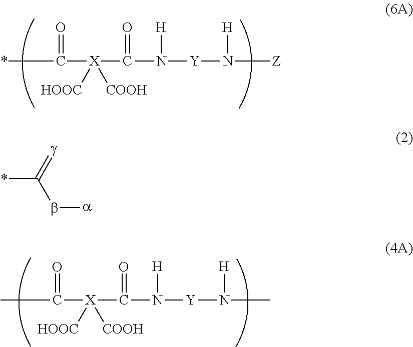

in Chemical Formulas (4A) and (6A), X represents a tetravalent tetracarboxylic acid residue having two or more carbon atoms and Y represents a divalent diamine residue having two or more carbon atoms. Z represents a structure represented by Chemical Formula (2); in Chemical Formula (2), α represents a monovalent hydrocarbon group having 2 or more carbon atoms; β and γ in Chemical Formula (2) each independently represent an oxygen atom or a sulfur atom; and * in Chemical Formula (2) indicates the bonding point of Z in Chemical Formula (6A).

In the second production method, in the (H) step of the first stage, only one acid anhydride group in the two acid anhydride groups that the tetracarboxylic dianhydride has is reacted with the terminal carbonyl group blocking agent. Therefore, in the (H) step of the first stage, the number of moles of the tetracarboxylic dianhydride is preferably set equal to or more than the number of moles of the terminal carbonyl group blocking agent. The number of moles of tetracarboxylic dianhydride is preferably equal to or more than twice the number of moles of the terminal carbonyl group blocking agent, more preferably equal to or more than five times the number of moles, and further preferably equal to or more than ten times the number of moles.

Here, the excess tetracarboxylic dianhydride to the terminal carbonyl group blocking agent remains unreacted in the (H) step of the first stage and is reacted with the diamine compound in the (I) step of the second stage.

In the (J) step of the third stage, the number of moles of the terminal amino group blocking agent is preferably one time to two times the number of moles of the terminal carbonyl group blocking agent used in the (H) step of the first stage. When the number of moles of the terminal amino group blocking agent is one time or more, unprotected amino groups are less likely to be generated at the terminal of the resin. When the number of moles of the terminal amino group blocking agent is two times or less, an increase in the amount of unreacted terminal amino group blocking agent can be prevented.

Here, in the first production method and the second production method of the resin having the repeating units represented by Chemical Formula (4A) as the main component, the number of moles of the diamine compound to be used and the number of moles of the tetracarboxylic acid to be used are preferably equal. When the numbers of moles are equal, the resin obtained by the method includes the partial structure represented by Chemical Formula (5A) and the partial structure represented by Chemical Formula (6A) in almost equal moles. When this resin is heated, the number of moles of the acid anhydride group and the number of moles of the amino group generated at terminal are likely to be equal. As a result, the degree of polymerization of the obtained polyimide resin is likely to increase.

As the above terminal amino group blocking agent, the terminal amino group blocking agent used in the method for producing the resin having the structure represented by Chemical Formula (1) can be used.

As the terminal carbonyl group blocking agent, alcohols or thiols having 2 to 10 carbon atoms are preferably used. Among them, alcohols are preferable. Specific Example include ethyl alcohol, n-propyl alcohol, n-butyl alcohol, n-pentyl alcohol, n-hexyl alcohol, n-heptyl alcohol, n-octyl alcohol, n-nonyl alcohol, n-decyl alcohol, isopropyl alcohol, isobutyl alcohol, sec-butyl alcohol, tert-butyl alcohol, isopentyl alcohol, sec-pentyl alcohol, tert-pentyl alcohol, isohexyl alcohol, sec-hexyl alcohol, cyclopropyl alcohol, cyclobutyl alcohol, cyclopentyl alcohol, cyclohexyl alcohol, cycloheptyl alcohol, cyclooctyl alcohol, norbornyl alcohol, and adamantyl alcohol. Among these alcohols, alcohols are isopropyl alcohol, cyclohexyl alcohol, tert-butyl alcohol, tert-pentyl alcohol, and the like. Among them, isopropyl alcohol, cyclohexyl alcohol, tert-butyl alcohol, and tert-pentyl alcohol are more preferable and the tert-butyl alcohol is most preferable.

In addition, in order to promote the reaction of alcohol or thiol, the reaction is preferably carried out with a catalyst being added. When the catalyst is added, excessive alcohol or thiol is not necessary to be used. Examples of such a catalyst include imidazoles and pyridines. Among these catalyst, 1-methylimidazole and N,N-dimethyl-4-aminopyridine are preferable.

Here, the carboxy group of the obtained resin may form a salt of an alkali metal ion, an ammonium ion, and an imidazolium ion or may form esters of a hydrocarbon group having 1 to 10 carbon atoms or an alkylsilyl group having 1 to 10 carbon atoms.

As the reaction solvent, the reaction solvent used in the method for producing the resin having the structure represented by Chemical Formula (1) can be used.

The resin composition according to the second aspect obtained by the above production method is preferably filtered with a filtration filter to remove foreign matters such as dirt. As the pore diameter and material of the filter, the same filter as the filter used in the production of the resin composition according to the first aspect may be used.

(Method for Producing Heat Resistant Resin Film)

Subsequently, a method for producing a heat resistant resin film using the resin composition according to the present invention will be described. The method includes applying the resin composition according to the present invention and heating the obtained applied film at a temperature of 220° C. or more.

First, a varnish being one of the embodiments of the resin composition according to the present invention is applied onto a support. Examples of the support include a wafer substrate such as silicon and gallium arsenide, a glass substrate such as sapphire glass, soda lime glass, and alkali-free glass, a metal substrate or a metal foil such as stainless steel and copper, and a ceramic substrate.

Examples of the method for applying the varnish include a spin coating method, a slit coating method, a dip coating method, a spray coating method, and a printing method. These methods may be used in combination. When the heat resistant resin film is used as a substrate for an electronic device, the resin composition is required to be applied onto a glass substrate having large size and thus the slit coating method is particularly preferably employed.

When the silt coating is carried out, change in viscosity of the resin composition causes change in applicability and thus a slit coating apparatus is required to be calibrated. Consequently, change in viscosity of the resin composition is preferably as small as possible. A preferable range of viscosity change is ±10% or less, more preferably ±5% or less and, further preferably ±3% or less. When the range of viscosity change is 10% or less, the film thickness uniformity of the obtained heat resistant resin film can be controlled within 5% or less.

Before the application, the support may be previously pretreated. Examples of the pretreatment include a method for treating the support surface by methods of spin coating, slit die coating, bar coating, dip coating, spray coating, and steam treatment using a solution in which a pretreatment agent is dissolved into a solvent such as isopropanol (2-propanol), ethanol, methanol, water, tetrahydrofuran, propylene glycol monomethyl ether acetate, propylene glycol monomethyl ether, ethyl lactate, and diethyl adipate in a concentration of 0.5% by mass to 20% by mass. The pretreated support may be subjected to a vacuum drying process, and thereafter may be subjected to heat treatment at 50° C. to 300° C. to promote the reaction between the support and the pretreatment agent, if necessary.

After application, the coating film of the resin composition is generally dried. As the drying method, drying under reduced pressure, drying by heating, or a combination thereof may be used. The method for drying under reduced pressure is carried out by, for example, placing the support on which a coating film is formed in a vacuum chamber and reducing the pressure inside the vacuum chamber. In addition, the method for drying by heating is carried out using a hot plate, an oven, infrared, or the like. When the hot plate is used, the coating film is held directly on the plate or on a jig such as a proxy pin placed on a plate to dry by heating.

Examples of the material of the proxy pin include a metal material such as aluminum or stainless steel or a synthetic resin such as a polyimide resin and “Teflon (registered trademark)”. The proxy pin made of any materials may be used as long as the material has heat resistance. Various heights of the proxy pin can be selected depending on the size of the support, the type of the (b) solvent used in the resin composition, and the drying method. The preferable height is about 0.1 mm to 10 mm. The heating temperature may vary depending on the type of the (b) solvent used in the resin composition and purpose. Heating is preferably carried out for 1 minute to several hours in a range of room temperature to 180° C. However, when the resin composition includes the (c) thermal acid generator, the heating is preferably carried out for 1 minute to several hours in a range of room temperature to 150° C. When the heating is carried out at a temperature more than the 150° C., the (c) thermal acid generator is decomposed to generate an acid. This causes deterioration in storage stability of the obtained applied film.

When the resin composition according to the present invention includes the (d) photoacid generator, a pattern can be formed form the coating film after drying by the method described below. The coating film is irradiated with actinic rays through a mask having a desired pattern to expose the coating film. Examples of the actinic rays used for exposure include ultraviolet rays, visible rays, electron rays, and X-rays. In the present invention, the i-line (365 nm), h-line (405 nm), and g-line (436 nm) of mercury lamps are preferably used. When coating film has positive photosensitivity, the exposure part is dissolved in the developing liquid. When coating film has negative photosensitivity, the exposure part is cured and becomes insoluble in the developing liquid.

After exposure, the desired pattern is formed using the developing liquid by removing the exposed part in the case of the positive type coating film or removing the unexposed part in the case of the negative type coating film. In either positive type coating film or negative type coating film, preferable examples of the developing liquid include an aqueous solution of a compound indicating alkalinity such as tetramethylammonium, diethanolamine, diethylaminoethanol, sodium hydroxide, potassium hydroxide, sodium carbonate, potassium carbonate, triethylamine, diethylamine, methylamine, dimethylamine, dimethylaminoethyl acetate, dimethylaminoethanol, dimethylaminoethyl methacrylate, cyclohexylamine, ethylenediamine, and hexamethylenediamine. In addition, in some cases, amides such as N-methyl-2-pyrrolidone, N,N-dimethylformamide, N,N-dimethylacetamide, dimethylacrylamide, and N,N-dimethylisobutylamide, esters such as γ-butyrolactone, ethyl lactate, and propylene glycol monomethyl ether acetate, sulfoxides such as dimethyl sulfoxide, ketones such as cyclopentanone, cyclohexanone, isobutyl ketone, and methyl isobutyl ketone, alcohols such as methanol, ethanol, and isopropanol (2-propanol) may be added to these alkaline aqueous solutions singly or in combination of several kinds of these solvents. In the case of the negative type coating film, the amides, esters, sulfoxides, ketones, and alcohols containing no alkaline aqueous solution may be used singly or in a combination of several kinds of these solvents. After development, rinsing treatment can be generally carried out with water. Here, the rinsing treatment may be carried out with esters such as ethyl lactate and propylene glycol monomethyl ether acetate and alcohols such as ethanol and isopropyl alcohol in addition to water.

Finally, the heat resistant resin film can be produced by carrying out heat treatment in a range of 180° C. or more and 600° C. or less and baking the coating film. In the present invention, in order to promote the thermal decomposition of Z in Chemical Formula (1) or Chemical Formula (6), that is, the structure represented by Chemical Formula (2), heating is preferably carried out at a temperature of 220° C. or more. In addition, when the resin composition includes the (c) thermal acid generator, the heating temperature is more preferably a temperature equal to or higher than the thermal decomposition starting temperature of the (c) thermal acid generator. When the heating is carried out at a temperature higher than the thermal decomposition starting temperature of the thermal acid generator, as described above, the acid generated from the (c) thermal acid generator promotes the thermal decomposition of the terminal structure Z in Chemical Formula (1) or Chemical Formula (6). Therefore, the polyimide film having excellent tensile elongation and maximum tensile stress can be obtained.

The obtained heat resistant resin film is suitably used for the surface protective film or interlayer insulating film of a semiconductor element, the insulating layer and spacer layer of the organic electroluminescence element (organic EL element), the planarization film of a thin-film transistor substrate, the insulating layer of an organic transistor, a binder for the electrode of a lithium ion secondary battery, and a semiconductor adhesive.

In addition, the heat resistant resin film according to the present invention is also suitably used for a substrate for an electronic device such as a flexible printed circuit board, a substrate for a flexible display, a substrate for a flexible electronic paper, a substrate for a flexible solar cell, and a substrate for a flexible color filter. In these applications, the preferable tensile elongation and maximum tensile stress of the heat resistant resin film is 15% or more and 150 MPa or more, respectively.

The thickness of the heat resistant resin film in the present invention is not particularly limited. When the heat resistant resin film is used as the substrate for an electronic device, the film thickness is preferably 5 μm or more. The thickness is more preferably 7 μm or more and further preferably 10 μm or more. When the thickness is 5 μm or more, sufficient mechanical properties can be obtained as the substrate for a flexible display.

When the heat resistant resin film is used as the substrate for an electronic device, a degree of in-plane uniformity of the film thickness of the heat-resistant resin film is preferably 5% or less. The degree of uniformity is more preferably 4% or less and further preferably 3% or less. When the degree of in-plane uniformity of the film thickness of the heat resistant resin film is 5% or less, the reliability of the electronic device to be formed on the heat resistant resin film is improved.

Hereinafter, a method for using the heat resistant resin film obtained by the production method according to the present invention as the substrate of an electronic device will be described. The method includes a step of forming a resin film in the method described above and a step of forming an electronic device on the resin film.

First, the heat resistant resin film is produced on a support such as a glass substrate by the production method according to the present invention.

Subsequently, the electronic device is formed by, for example, forming a driving element and electrodes on the heat resistant resin film. For example, when the electronic device is an image display device, the electronic device is formed by, for example, forming pixel driving elements or coloring pixels. When the image display device is an organic EL display, TFT being an image driving element, a first electrode, an organic EL light emitting device, a second electrode, and a sealing film are formed in this order. In the case of the color filter, the black matrix is formed, if necessary, and thereafter coloring pixels such as red, green, and blue are formed.

A gas barrier film may be provided between the heat resistant resin film and the pixel driving elements or the coloring pixels, if necessary. By providing the gas barrier film, generation of deterioration in the pixel driving elements and coloring pixels due to the penetration of moisture and oxygen through the heat resistant resin film from the outside of the image display device can be prevented. As the gas barrier film, a single film of an inorganic film such as a silicon oxide film (SiOx), a silicon nitrogen film (SiNy), a silicon oxynitride film (SiOxNy) or a film formed by laminating a plurality of types of inorganic films exemplified above is used. A method for forming the gas barrier film is carried out using a method of, for example, chemical vapor deposition (CVD) or physical vapor deposition (PVD). Furthermore, as the gas barrier film, a film formed by alternately laminating these inorganic films and organic films such as a polyvinyl alcohol film can also be used.

Finally, the heat resistant resin film is peeled from the support to give an electronic device including the heat resistant resin film. Examples of a method for peeling the support and the heat resistant resin film at the interface include a method for using laser, a method for mechanically peeling the support and the heat resistant resin film, and a method for etching the support. In the method for using laser, the support can be peeled without damaging the image display device by irradiating the support such as a glass substrate with the laser from the side on which the image display element is not formed. In addition, a primer layer for easily peeling the support may be provided between the support and the heat resistant resin film.

### Example

Hereinafter, the present invention will be described with reference to Examples and the like. The present invention, however, is not limited by Examples.

(1) Preparation of Polyimide Film (Heat Resistant Resin Film)

A glass substrate having a size of 8 inches was spin-coated with a varnish using a coating device Mark-7 (manufactured by Tokyo Electron Limited) and the coated varnish was dried at 110° C. for 8 minutes. Subsequently, the temperature of the dried coated varnish was raised from 50° C. at a rate of 4° C./min and the coated varnish was heated at 350° for 30 minutes under nitrogen atmosphere (oxygen content 20 ppm or less) using Inert Oven (INH-21CD, manufactured by Koyo Thermo Systems Co., Ltd.). After cooling, the glass substrate was immersed in hydrofluoric acid for 4 minutes to peel the polyimide film from the glass substrate and the obtained polyimide film was dried with blown air.

(2) Tensile Elongation, Maximum Tensile Stress, and Young's Modulus of Heat Resistant Resin Film

These physical properties were measured in accordance with Japanese Industrial Standards (JIS K 7127:1999) using Tensilon Universal Tester (RTM-100, manufactured by Orientec Co., Ltd.).

Measurement conditions were determined to be a width of a test specimen of 10 mm, a chuck distance of 50 mm, a test speed of 50 mm/min, and a measured sample number n of 10.

(3) Measurement of Particles in Liquid

The number of particles (particle diameter 1 μm or more) in the varnish was measured using Liquid-borne Particle Counter (XP-65, manufactured by RION Co., Ltd.).

(4) Measurement of Content of Compound Represented by Chemical Formula (3).

An analytical curve was prepared from the standard samples obtained in Synthesis Examples A and B using Liquid Chromatograph Mass Spectrometer (liquid chromatograph: LC-20A, manufactured by Shimadzu Corporation, mass spectrometer: API 4000, manufactured by AB Sciex Pte. Ltd.). Subsequently, the content of the compound represented by Chemical Formula (3) in the varnish was measured using the same apparatus.

(5) Measurement of ¹H-NMR

¹H-NMR spectrum was measured using a nuclear magnetic resonance apparatus (EX-270, manufactured by JEOL Ltd.) using deuterated dimethylsulfoxide as a deuterated solvent.

(6) Viscosity

The viscosity of the varnish was measured at 25° C. using a viscometer (TVE-22H, manufactured by Toki Sangyo Co., Ltd).

(7) Storage of Varnish

The varnishes obtained in each Synthesis Example were allowed to stand at 23° C. or 30° C. for 30 days or 60 days in clean bottles (manufactured by AICELLO CORPORATION). The viscosity was measured with the method in (6) using the varnish after storage. The tensile elongation, maximum tensile stress, Young's modulus, and the number of particles in the liquid were measured with the same methods as the methods in (2) and (3) for the polyimide film prepared from the varnish after storage with the method in (1). The change rate of the viscosity was determined in accordance with the following formula.

Change rate in viscosity (%)=(Viscosity after storage−Viscosity before storage)/Viscosity before storage×100

(8) Measurement of Degree of in-Plane Uniformity of the Film Thickness of Heat Resistant Resin Film

The polyimide film was prepared on a glass substrate in the same method as the method in (1). The film thicknesses of the heat resistant resin film were measured at intervals of 10 mm in a part of the area excluding 10 mm from the edge of the glass substrate using a film thickness measuring device (RE-8000, manufactured by Screen Co., Ltd.). The degree of in-plane uniformity of the film thickness is determined from the measured thicknesses in accordance with the following formula.

Degree of in-plane uniformity of film thickness (%)=(Maximum value of film thickness−Minimum value of film thickness)/(Average value of film thickness×2)×100

(9) Measurement of Thermal Decomposition Starting Temperature

In the measurement, a differential scanning calorimetry measurement apparatus (Shimadzu Corporation DSC-50) was used. A sample ((c) thermal acid generator) was encapsulated in a cell made of aluminum and the temperature of the sample was raised from room temperature to 400° C. in a rate of 10° C./min to measure the thermal decomposition starting temperature. The temperature of the apex of the measured endothermic peak was determined to be the thermal decomposition starting temperature.

Abbreviations of the compounds used in the following Synthesis Examples are listed below.

PMDA: Pyromellitic dianhydride
BPDA: 3,3′,4,4′-Biphenyltetracarboxylic dianhydride
PDA: p-Phenylenediamine
DAE: 4,4′-Diaminodiphenyl ether
DIBOC: Di-tert-butyl dicarbonate
NMP: N-methyl-2-pyrrolidone

### THF: Tetrahydrofuran.

TAG-1 (thermal decomposition starting temperature: 213° C.)

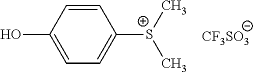

TAG-2 (thermal decomposition starting temperature: 203° C.)

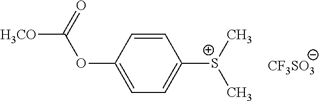

TAG-3 (thermal decomposition starting temperature: 167° C.)

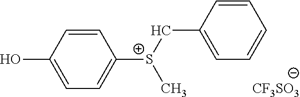

TAG-4 (thermal decomposition starting temperature: 160° C.)

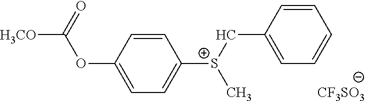

TAG-5 (thermal decomposition starting temperature: 149° C.)

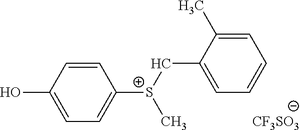

TAG-6 (thermal decomposition starting temperature: 145° C.)

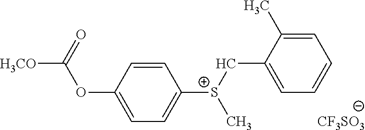

TAG-7 (thermal decomposition starting temperature: 129° C.)

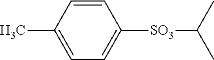

### Synthesis Example A

A 200 mL four-neck flask was equipped with a thermometer and a stirring rod with a stirring blade. Subsequently, 30 g of THF was charged into the flask under dry nitrogen flow and cooled to 0° C. 5.407 g (50.00 mmol) of PDA was charged with stirring and washed off with 10 g of THF. Subsequently, a solution in which 22.92 g (105.0 mmol) of DIBOC was diluted in 40 g of THF was added dropwise over 1 hour. After completion of dropwise addition, the temperature of the reaction solution was raised to room temperature. After a while, precipitate appeared in the reaction solution. After 12 hours, the precipitate was collected from the reaction solution by filtration and dried at 50° C. ¹H-NMR spectrum of the precipitate was measured to confirm that the precipitate was a compound represented by Chemical Formula (51). This precipitate was used as a standard sample.

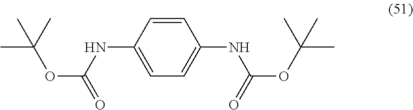 [SMILES: CC(C)(C)OC(=O)Nc1ccc(NC(=O)OC(C)(C)C)cc1]

### Synthesis Example B

A 200 mL four-neck flask was equipped with a thermometer and a stirring rod with a stirring blade. Subsequently, 30 g of THF was charged into the flask under dry nitrogen flow and cooled to 0° C. 10.01 g (50.00 mmol) of DAE was charged with stirring and the washed off with 10 g of THF. Subsequently, a solution in which 22.92 g (105.0 mmol) of DIBOC was diluted in 40 g of THF was added dropwise over 1 hour. After completion of dropwise addition, the temperature of the reaction solution was raised to room temperature. After a while, precipitate appeared in the reaction solution. After 12 hours, the precipitate was collected from the reaction solution by filtration and dried at 50° C. ¹H-NMR spectrum of the precipitate was measured to confirm that the precipitate was a compound represented by Chemical Formula (52). This precipitate was used as a standard sample.

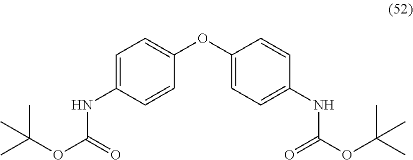 [SMILES: CC(C)(C)OC(=O)Nc1ccc(Oc2ccc(NC(=O)OC(C)(C)C)cc2)cc1]

### Synthesis Example 1

A 300 mL four-neck flask was equipped with a thermometer and a stirring rod with a stirring blade. Subsequently, 90 g of NMP was charged into the flask under dry nitrogen flow and the temperature was raised to 40° C. After the temperature rising, 10.81 g (100.0 mmol) of PDA was charged with stirring and washed off with 10 g of NMP. After checking dissolution of PDA, 26.48 g (90.00 mmol) of BPDA was charged and washed off with 10 g of NMP. After 4 hours, 3.274 g (15.00 mmol) of DIBOC was added and washed off with 10 g of NMP. After further 1 hour, 2.942 g (10.00 mmol) of BPDA was added and the washed off with 10 g of NMP. After 2 hours, the resultant reaction solution was cooled. The reaction solution was filtered with a filter having a pore diameter of 0.2 μm to prepare a varnish.

### Synthesis Example 2

A 300 mL four-neck flask was equipped with a thermometer and a stirring rod with a stirring blade. Subsequently, 90 g of NMP was charged into the flask under dry nitrogen flow and the temperature was raised to 40° C. After the temperature rising, 10.81 g (100.0-mmol) of PDA was charged with stirring and washed off with 10 g of NMP. After checking the dissolution of PDA, a solution in which 3.274 g (15.00 mmol) of DIBOC was diluted in 20 g of NMP was added dropwise over 10 minutes. After 1 hour from completion of the dropwise addition, 29.42 g (100.00 mmol) of BPDA was added and washed off with 10 g of NMP. After 4 hours, the resultant reaction solution was cooled. The reaction solution was filtered with a filter having a pore diameter of 0.2 μm to prepare a varnish.

### Synthesis Example 3

A 300 mL four-neck flask was equipped with a thermometer and a stirring rod with a stirring blade. Subsequently, 90 g of NMP was charged into the flask under dry nitrogen flow and the temperature was raised to 40° C. After the temperature rising, 10.81 g (100.0 mmol) of PDA was charged with stirring and washed off with 10 g of NMP. After checking the dissolution of PDA, a solution in which 3.274 g (15.00 mmol) of DIBOC was diluted in 20 g of NMP was added dropwise over 20 minutes. After 1 hour from completion of the dropwise addition, 29.42 g (100.00 mmol) of BPDA was added and washed off with 10 g of NMP. After 4 hours, the resultant reaction solution was cooled. The reaction solution was filtered with a filter having a pore diameter of 0.2 μm to prepare a varnish.

### Synthesis Example 4

A 300 mL four-neck flask was equipped with a thermometer and a stirring rod with a stirring blade. Subsequently, 90 g of NMP was charged into the flask under dry nitrogen flow and the temperature was raised to 40° C. After the temperature rising, 10.81 g (100.0 mmol) of PDA was charged with stirring and washed off with 10 g of NMP. After checking the dissolution of PDA, a solution in which 3.274 g (15.00 mmol) of DIBOC was diluted in 20 g of NMP was added dropwise over 30 minutes. After 1 hour from completion of the dropwise addition, 29.42 g (100.00 mmol) of BPDA was added and washed off with 10 g of NMP. After 4 hours, the resultant reaction solution was cooled. The reaction solution was filtered with a filter having a pore diameter of 0.2 μm to prepare a varnish.

### Synthesis Example 5

A 300 mL four-neck flask was equipped with a thermometer and a stirring rod with a stirring blade. Subsequently, 90 g of NMP was charged into the flask under dry nitrogen flow and the temperature was raised to 40° C. After the temperature rising, 10.81 g (100.0 mmol) of PDA was charged with stirring and washed off with 10 g of NMP. After checking the dissolution of PDA, a solution of 3.274 g (15.00 mmol) of DIBOC was diluted in 20 g of NMP was added dropwise over 60 minutes. After 1 hour from completion of the dropwise addition, 29.42 g (100.00 mmol) of BPDA was added and washed off with 10 g of NMP. After 4 hours, the resultant reaction solution was cooled. The reaction solution was filtered with a filter having a pore diameter of 0.2 μm to prepare a varnish.

### Synthesis Example 6

A 300 mL four-neck flask was equipped with a thermometer and a stirring rod with a stirring blade. Subsequently, 90 g of NMP was charged into the flask under dry nitrogen flow and the temperature was raised to 40° C. After the temperature rising, 10.81 g (100.0 mmol) of PDA was charged with stirring and washed off with 10 g of NMP. After checking the dissolution of PDA, a solution in which 3.274 g (15.00 mmol) of DIBOC was diluted in 20 g of NMP was added dropwise over 120 minutes. After 1 hour from completion of the dropwise addition, 29.42 g (100.00 mmol) of BPDA was added and washed off with 10 g of NMP. After 4 hours, the resultant reaction solution was cooled. The reaction solution was filtered with a filter having a pore diameter of 0.2 μm to prepare a varnish.

### Synthesis Example 7

A 300 mL four-neck flask was equipped with a thermometer and a stirring rod with a stirring blade. Subsequently, 80 g of NMP was charged into the flask under dry nitrogen flow and the temperature was raised to 40° C. After the temperature rising, 20.02 g (100.0 mmol) of DAE was charged with stirring and washed off with 10 g of NMP. After checking dissolution of DAE, 19.63 g (90.00 mmol) of PMDA was charged and washed off with 10 g of NMP. After 2 hours, 3.274 g (15.00 mmol) of DIBOC was added and washed off with 10 g of NMP. After further 1 hour, 2.181 g (10.00 mmol) of PMDA was added and the washed off with 10 g of NMP. After 2 hours, the resultant reaction solution was cooled. The reaction solution was filtered with a filter having a pore diameter of 0.2 μm to prepare a varnish.

### Synthesis Example 8

A 300 mL four-neck flask was equipped with a thermometer and a stirring rod with a stirring blade. Subsequently, 90 g of NMP was charged into the flask under dry nitrogen flow and the temperature was raised to 40° C. After the temperature rising, 20.02 g (100.0 mmol) of DAE was charged with stirring and washed off with 10 g of NMP. After checking the dissolution of DAE, a solution in which 3.274 g (15.00 mmol) of DIBOC was diluted in 20 g of NMP was added dropwise over 20 minutes. After 1 hour from completion of the dropwise addition, 21.81 g (100.00 mmol) of PMDA was added and washed off with 10 g of NMP. After 2 hours, the resultant reaction solution was cooled. The reaction solution was filtered with a filter having a pore diameter of 0.2 μm to prepare a varnish.

### Synthesis Example 9

A 300 mL four-neck flask was equipped with a thermometer and a stirring rod with a stirring blade. Subsequently, 90 g of NMP was charged into the flask under dry nitrogen flow and the temperature was raised to 40° C. After the temperature rising, 10.81 g (100.0 mmol) of PDA was charged with stirring and washed off with 10 g of NMP. After checking the dissolution of PDA, 3.274 g (15.00 mmol) of DIBOC was added dropwise over 30 minutes and washed off with 20 g of NMP. After 1 hour from completion of the dropwise addition, 29.42 g (100.00 mmol) of BPDA was added and washed off with 10 g of NMP. After 4 hours, the resultant reaction solution was cooled. The reaction solution was filtered with a filter having a pore diameter of 0.2 μm to prepare a varnish.

### Synthesis Example 10

A 300 mL four-neck flask was equipped with a thermometer and a stirring rod with a stirring blade. Subsequently, 90 g of NMP was charged into the flask under dry nitrogen flow and the temperature was raised to 40° C. After the temperature rising, 10.81 g (100.0 mmol) of PDA was charged with stirring and washed off with 10 g of NMP. After checking the dissolution of PDA, 3.274 g (15.00 mmol) of DIBOC was added over 1 minute and washed off with 20 g of NMP. After 1 hour from completion of the dropwise addition, 29.42 g (100.00 mmol) of BPDA was added and washed off with 10 g of NMP. After 4 hours, the resultant reaction solution was cooled. The reaction solution was filtered with a filter having a pore diameter of 0.2 μm to prepare a varnish.

### Synthesis Example 11

A 300 mL four-neck flask was equipped with a thermometer and a stirring rod with a stirring blade. Subsequently, 90 g of NMP was charged into the flask under dry nitrogen flow and the temperature was raised to 40° C. After the temperature rising, 20.02 g (100.0 mmol) of DAE was charged with stirring and washed off with 10 g of NMP. After checking the dissolution of DAE, a solution in which 3.274 g (15.00 mmol) of DIBOC was diluted in 20 g of NMP was added dropwise over 1 minute. After 1 hour, 21.81 g (100.00 mmol) of PMDA was added and washed off with 10 g of NMP. After 2 hours, the resultant reaction solution was cooled. The reaction solution was filtered with a filter having a pore diameter of 0.2 μm to prepare a varnish.

### Example 1

A: The number of particles in liquid was measured using the varnish obtained in Synthesis Example 1 and a polyimide film was prepared by the method in (1) to measure the tensile elongation, the maximum tensile stress, and Young's modulus.

B: The varnish obtained in Synthesis Example 1 was allowed to stand at 23° C. for 30 days or in a clean bottle (manufactured by AICELLO CORPORATION). Thereafter, the number of particles in liquid of the varnish after the storage was measured and a polyimide film was prepared to measure the tensile elongation, the maximum tensile stress, and Young's modulus.

### Examples 2 to 8 and Comparative Examples 1 to 3

As listed in Tables 1 and 2, the varnishes obtained in Synthesis Examples 2 to 11 were used to evaluate in the same manner as Example 1.

The evaluation results of Examples 1 to 8 and Comparative Examples 1 to 3 are listed in Tables 1 and 2.

TABLE 1

| | | | 1 | | 2 | | 3 | | 4 | | 5 | | 6 | | 7 | | 8 | |
|---|---|---|---|---|---|---|---|---|---|---|---|---|---|---|---|---|---|---|
| Example | | | A | B | A | B | A | B | A | B | A | B | A | B | A | B | A | B |
| Synthesis Example | | | 1 | | 2 | | 3 | | 4 | | 5 | | 6 | | 7 | | 8 | |
| Acid | BPDA | Molar | 100 | | 100 | | 100 | | 100 | | 100 | | 100 | | 100 | | 100 | |
| di- | PMDA | ratio | | | | | | | | | | | | | | | | |
| anhydride | | | | | | | | | | | | | | | | | | |
| Diamine | PDA | | 100 | | 100 | | 100 | | 100 | | 100 | | 100 | | 100 | | 100 | |
| compound | DAE | | | | | | | | | | | | | | | | | |
| Terminal | DIBOC | | 15 | | 15 | | 15 | | 15 | | 15 | | 15 | | 15 | | 15 | |
| blocking | | | | | | | | | | | | | | | | | | |
| agent | | | | | | | | | | | | | | | | | | |

| Concentration of | ppm | 6 | | 38 | | 18 | | 8 | | 4 | | 3 | | 5 | | 12 | |
|---|---|---|---|---|---|---|---|---|---|---|---|---|---|---|---|---|---|
| compound | by | | | | | | | | | | | | | | | | |
| represented | mass | | | | | | | | | | | | | | | | |
| by Chemical | | | | | | | | | | | | | | | | | |
| Formula (3) | | | | | | | | | | | | | | | | | |
| Storage days | Day | 0 | 30 | 0 | 30 | 0 | 30 | 0 | 30 | 0 | 30 | 0 | 30 | 0 | 30 | 0 | 30 |
| Particles | Par- | 8 | 8 | 9 | 22 | 8 | 17 | 8 | 9 | 5 | 5 | 4 | 4 | 7 | 7 | 7 | 13 |
| | ticle/ | | | | | | | | | | | | | | | | |
| | mL | | | | | | | | | | | | | | | | |
| Tensile elongation | % | 25 | 26 | 26 | 25 | 25 | 25 | 24 | 25 | 25 | 25 | 24 | 25 | 105 | 104 | 104 | 102 |
| Maximum tensile | MPa | 301 | 303 | 304 | 305 | 304 | 302 | 303 | 303 | 306 | 305 | 303 | 302 | 231 | 230 | 228 | 229 |
| stress | | | | | | | | | | | | | | | | | |
| Young's modulus | GPa | 7.0 | 7.1 | 6.9 | 6.9 | 6.9 | 7.0 | 7.0 | 6.9 | 7.0 | 7.0 | 7.0 | 6.9 | 1.8 | 1.7 | 1.9 | 1.9 |

TABLE 2

| | 1 | | 2 | | 3 | |
|---|---|---|---|---|---|---|
| Comparative Example | A | B | A | B | A | B |

| Synthesis Example | | | 9 | 10 | 11 |
|---|---|---|---|---|---|
| Acid | BPDA | Molar | 100 | 100 | |
| dian- | PMDA | ratio | | | 100 |
| hydride | | | | | |
| Diamine | PDA | | 100 | 100 | |
| com- | DAE | | | | 100 |
| pound | | | | | |
| Terminal | DIBOC | | 15 | 15 | 15 |
| blocking | | | | | |
| agent | | | | | |

| Concentration | ppm by | 44 | | 65 | | 47 | |
|---|---|---|---|---|---|---|---|
| of compound | mass | | | | | | |
| represented | | | | | | | |
| by Chemical | | | | | | | |
| Formula (3) | | | | | | | |
| Storage days | Day | 0 | 30 | 0 | 30 | 0 | 30 |
| Particles | Particle/ | 8 | 113 | 9 | 303 | 7 | 142 |
| | mL | | | | | | |
| Tensile | % | 25 | 9 | 24 | 5 | 103 | 61 |
| elongation | | | | | | | |
| Maximum | MPa | 303 | 194 | 302 | 107 | 229 | 136 |
| tensile | | | | | | | |
| stress | | | | | | | |
| Young's | GPa | 7.0 | 6.8 | 7.0 | 6.5 | 1.8 | 1.7 |
| modulus | | | | | | | |

### Example 11

C: The viscosity was measured using the varnish obtained in Synthesis Example 1. The calibration of a slit coating apparatus (manufactured by Toray Engineering Co., Ltd.) was carried out using the same varnish. Subsequently, the varnish was applied onto an alkali-free glass substrate having a length of 350 mm, a width of 300 mm, and a thickness of 0.5 mm (AN-100, manufactured by Asahi Glass Co., Ltd.) using the same slit coating apparatus. Subsequently, the applied varnish was dried with VCD and a hot plate and thereafter a heat resistant resin film was formed on the glass substrate by heating at 500° C. for 30 minutes under nitrogen atmosphere (oxygen content: 20 ppm or less) using a gas oven (INH-21CD, manufactured by Koyo Thermo Systems Co., Ltd.). The degree of in-plane uniformity of the film thickness of the formed heat resistant resin film was measured.

D: The varnish obtained in Synthesis Example 1 was allowed to stand at 23° C. for 30 days or in a clean bottle (manufactured by AICELLO CORPORATION). Thereafter, the viscosity of the varnish after the storage was measured. The same varnish was applied on a glass substrate in the same manner as C using the slit coating apparatus after calibration in C. Subsequently, the same was C, a heat resistant resin film was formed on a glass substrate and the degree of in-plane uniformity of the film thickness of the formed heat resistant resin film was measured.

### Examples 12 to 16

As listed in Table 3, the varnishes obtained in Synthesis Examples 2 to 6 were used to evaluate in the same manner as Example 11.

The evaluation results of Examples 11 to 16 are listed in Table 3.

TABLE 3

| | | | | | |
|---|---|---|---|---|---|
| 11 | 12 | 13 | 14 | 15 | 16 |

| | | | | | | | | | | | | |
|---|---|---|---|---|---|---|---|---|---|---|---|---|
| Example | C | D | C | D | C | D | C | D | C | D | C | D |

| Synthesis Example | | | 1 | 2 | 3 | 4 | 5 | 6 |
|---|---|---|---|---|---|---|---|---|
| Acid | BPDA | Molar | 100 | 100 | 100 | 100 | 100 | 100 |
| dianhydride | PMDA | ratio | | | | | | |
| Diamine | PDA | | 100 | 100 | 100 | 100 | 100 | 100 |
| compound | DAE | | | | | | | |
| Terminal | DIBOC | | 15 | 15 | 15 | 15 | 15 | 15 |
| blocking | | | | | | | | |
| agent | | | | | | | | |

| Concentration of | ppm by | 6 | | 38 | | 18 | | 8 | | 4 | | 3 | |
|---|---|---|---|---|---|---|---|---|---|---|---|---|---|
| compound represented | mass | | | | | | | | | | | | |
| by Chemical Formula | | | | | | | | | | | | | |
| (3) | | | | | | | | | | | | | |
| Storage days | Day | 0 | 30 | 0 | 30 | 0 | 30 | 0 | 30 | 0 | 30 | 0 | 30 |
| Viscosity | cP | 3162 | 3385 | 3190 | 3240 | 3174 | 3278 | 3133 | 3301 | 3120 | 3349 | 3099 | 3528 |
| Change rate in | % | | +7.1 | | +1.6 | | +3.3 | | +5.4 | | +7.3 | | +13.8 |
| viscosity | | | | | | | | | | | | | |
| Degree of in-plane | % | 3.0 | 4.8 | 3.0 | 3.1 | 3.1 | 4.0 | 3.0 | 4.5 | 3.1 | 4.9 | 3.0 | 7.0 |
| uniformity of film | | | | | | | | | | | | | |
| thickness of heat | | | | | | | | | | | | | |
| resistant resin film | | | | | | | | | | | | | |

### Example 21

A gas barrier film made of laminated SiO₂ and Si₃N₄ was formed by CVD on the obtained heat resistant resin film in B of Example 1. Subsequently, a TFT was formed and an insulating film made of Si₃N₄ was formed so as to cover the TFT. Subsequently, after a contact hole was formed in the insulating film, a wiring connected to the TFT through the contact hole was formed.

Moreover, a planarization film was formed in order to planarize unevenness due to the formation of the wiring. Subsequently, a first electrode made of ITO was formed on the obtained planarization film with the first electrode being connected to the wiring. Thereafter, a resist was applied, prebaked, exposed through a mask having a desired pattern, and developed. A pattern was processed by wet etching using ITO etchant with this resist pattern as a mask. Thereafter, the resist pattern was peeled using a resist removing solution (a mixed solution of monoethanolamine and diethylene glycol monobutyl ether). The substrate after peeling was washed with water and heated and dehydrated to obtain an electrode substrate with a planarization film. Subsequently, an insulating film having a shape of covering the peripheral edge of the first electrode was formed.

Moreover, a hole transport layer, an organic light emitting layer, and an electron transport layer were provided by sequentially depositing these layers in a vacuum deposition apparatus through a mask having a desired pattern. Subsequently, a second electrode made of Al/Mg was formed on the entire upper surface of the substrate. Further, a sealing film made of laminated SiO₂ and Si₃N₄ was formed by CVD. Finally, the support and the heat resistant resin film was peeled at the interface by irradiating the glass substrate with laser (wavelength: 308 nm) from the side on which the heat resistant resin film is not formed.

As described above, an organic EL display device formed on the heat resistant resin film was obtained. When voltage was applied to the organic EL display device through a driving circuit, the organic EL display device provided excellent emission.

### Comparative Example 22

An organic EL display device was formed on the heat resistant resin film obtained in B of Comparative Example 1 in the same manner as Example 21. When voltage was applied to the organic EL display device through a driving circuit, however, light emission properties were poor due to dark spots generated by unevenness of the surface of the heat resistant resin film originated from the particles in the varnish.

### Synthesis Example 101

A 300 mL four-neck flask was equipped with a thermometer and a stirring rod with a stirring blade. Subsequently, 90 g of NMP was charged into the flask under dry nitrogen flow and the temperature was raised to 40° C. After the temperature rising, 10.81 g (100.0 mmol) of PDA was charged with stirring and washed off with 10 g of NMP. After checking the dissolution of PDA, a solution in which 2.183 g (10.00 mmol) of DIBOC was diluted in 20 g of NMP was added dropwise over 30 minutes. After 1 hour from completion of the dropwise addition, 29.42 g (100.00 mmol) of BPDA was added and washed off with 10 g of NMP. After 2 hours, 0.4607 g (10.00 mmol) of ethanol was added and washed off with 10 g of NMP. After 1 hour, the resultant reaction solution was cooled. The reaction solution was diluted with NMP so that the viscosity of the reaction solution was about 2000 cP and the resultant solution was filtered with a filter having a pore diameter of 0.2 μm to prepare a varnish.

### Synthesis Example 102

A 300 mL four-neck flask was equipped with a thermometer and a stirring rod with a stirring blade. Subsequently, 90 g of NMP was charged into the flask under dry nitrogen flow and the temperature was raised to 40° C. After the temperature rising, 10.81 g (100.0 mmol) of PDA was charged with stirring and washed off with 10 g of NMP. After checking the dissolution of PDA, a solution in which 2.183 g (10.00 mmol) of DIBOC was diluted in 20 g of NMP was added dropwise over 30 minutes. After 1 hour from completion of the dropwise addition, 29.42 g (100.00 mmol) of BPDA was added and washed off with 10 g of NMP. After 4 hours, 0.4607 g (10.00 mmol) of ethanol and 8.210 mg (0.1000 mmol) of 1-methylimidazole were added and washed off with 10 g of NMP. After 1 hour, the resultant reaction solution was cooled. The reaction solution was diluted with NMP so that the viscosity of the reaction solution was about 2000 cP and the resultant solution was filtered with a filter having a pore diameter of 0.2 μm to prepare a varnish.

### Synthesis Example 103

A varnish was prepared in the same manner as Synthesis Example 102 except that 0.6010 g (10.00 mmol) of isopropyl alcohol was used instead of ethanol.

### Synthesis Example 104

A varnish was prepared in the same manner as Synthesis Example 101 except that 0.7412 g (10.00 mmol) of tert-butyl alcohol was used instead of ethanol.

### Synthesis Example 105

A varnish was prepared in the same manner as Synthesis Example 102 except that 0.7412 g (10.00 mmol) of tert-butyl alcohol was used instead of ethanol.

### Synthesis Example 106

A 300 mL four-neck flask was equipped with a thermometer and a stirring rod with a stirring blade. Subsequently, 90 g of NMP was charged into the flask under dry nitrogen flow and the temperature was raised to 40° C. After the temperature rising, 20.02 g (100.0 mmol) of DAE was charged with stirring and washed off with 10 g of NMP. After checking the dissolution of DAE, a solution in which 2.183 g (10.00 mmol) of DIBOC was diluted in 20 g of NMP was added dropwise over 30 minutes. After 1 hour from completion of the dropwise addition, 21.81 g (100.00 mmol) of PMDA was added and washed off with 10 g of NMP. After 2 hours, 0.4607 g (10.00 mmol) of ethanol and 8.210 mg (0.1000 mmol) of 1-methylimidazole were added and washed off with 10 g of NMP. After 1 hour, the resultant reaction solution was cooled. The reaction solution was diluted with NMP so that the viscosity of the reaction solution was about 2000 cP and the resultant solution was filtered with a filter having a pore diameter of 0.2 μm to prepare a varnish.

### Synthesis Example 107

A 300 mL four-neck flask was equipped with a thermometer and a stirring rod with a stirring blade. Subsequently, 90 g of NMP was charged into the flask under dry nitrogen flow and the temperature was raised to 40° C. After the temperature rising, 10.81 g (100.0 mmol) of PDA was charged with stirring and washed off with 10 g of NMP. After checking the dissolution of PDA, a solution in which 2.183 g (10.00 mmol) of DIBOC was diluted in 20 g of NMP was added dropwise over 30 minutes. After 1 hour from completion of the dropwise addition, 29.42 g (100.00 mmol) of BPDA was added and washed off with 10 g of NMP. After 4 hours, the resultant reaction solution was cooled. The reaction solution was diluted with NMP so that the viscosity was of the reaction solution about 2000 cP and the resultant solution was filtered with a filter having a pore diameter of 0.2 μm to prepare a varnish.

### Synthesis Example 108

A 300 mL four-neck flask was equipped with a thermometer and a stirring rod with a stirring blade. Subsequently, 90 g of NMP was charged into the flask under dry nitrogen flow and the temperature was raised to 40° C. After the temperature rising, 29.42 g (100.0 mmol) of BPDA was charged with stirring and washed off with 10 g of NMP. Subsequently, 0.7412 g (10.00 mmol) of tert-butyl alcohol was added and the washed off with 10 g of NMP. After 1 hour, 10.81 g (100.00 mmol) of PDA was added and washed off with 10 g of NMP. After 4 hours, the resultant reaction solution was cooled. The reaction solution was diluted with NMP so that the viscosity of the reaction solution was about 2000 cP and the resultant solution was filtered with a filter having a pore diameter of 0.2 μm to prepare a varnish.

### Synthesis Example 109

A 300 mL four-neck flask was equipped with a thermometer and a stirring rod with a stirring blade. Subsequently, 90 g of NMP was charged into the flask under dry nitrogen flow and the temperature was raised to 40° C. After the temperature rising, 20.02 g (100.0 mmol) of DAE was charged with stirring and washed off with 10 g of NMP. After checking the dissolution of DAE, a solution in which 2.183 g (10.00 mmol) of DIBOC was diluted in 20 g of NMP was added dropwise over 30 minutes. After 1 hour from completion of the dropwise addition, 21.81 g (100.00 mmol) of PMDA was added and washed off with 10 g of NMP. After 2 hours, the resultant reaction solution was cooled. The reaction solution was diluted with NMP so that the viscosity of the reaction solution was about 2000 cP and the resultant solution was filtered with a filter having a pore diameter of 0.2 Lm to prepare a varnish.

### Example 101

E: The viscosity and the degree of in-plane uniformity of the film thickness of the heat resistant resin film were measured using the varnish obtained in Synthesis Example 101 in the same manner as Example 11.

F: The viscosity and the degree of in-plane uniformity of the film thickness of the heat resistant resin film were also measured in the same manner as Example 11 using the varnish obtained in Synthesis Example 101 stored at 30° C. for 60 days in a clean bottle (manufactured by AICELLO CORPORATION).

### Examples 102 to 106, Reference Example 101, Comparative Example 102, and Reference Example 103

As listed in Tables 4 and 5, the varnishes obtained in Synthesis Examples 102 to 109 were used to evaluate in the same manner as Example 11. Here, in Example 105 and Reference Example 103, the heating temperature in a gas oven was set to 400° C.

The evaluation results of Examples 101 to 106, Reference Example 101, Comparative Example 102, and Reference Example 103 are listed in Tables 4 and 5.

TABLE 4

| | | | | | |
|---|---|---|---|---|---|
| 101 | 102 | 103 | 104 | 105 | 106 |

| | | | | | | | | | | | | |
|---|---|---|---|---|---|---|---|---|---|---|---|---|
| Example | E | F | E | F | E | F | E | F | E | F | E | F |

| Synthesis Example | | | 101 | 102 | 103 | 104 | 105 | 106 |
|---|---|---|---|---|---|---|---|---|
| Acid | BPDA | Molar | 100 | 100 | 100 | 100 | 100 | |
| dianhydride | PMDA | ratio | | | | | | 100 |
| Diamine | PDA | | 100 | 100 | 100 | 100 | 100 | |
| compound | DAE | | | | | | | 100 |
| Terminal | DIBOC | | 10 | 10 | 10 | 10 | 10 | 10 |
| blocking | Ethanol | | 10 | 10 | | | | 10 |
| agent | Isopropyl | | | | 10 | | | |
| | alcohol | | | | | | | |
| | Tert-Butyl | | | | | 10 | 10 | |
| | alcohol | | | | | | | |
| Catalyst | 1-Methyl | | | 0.1 | 0.1 | | 0.1 | 0.1 |
| | imidazole | | | | | | | |

| | | | | | | | | | | | | | |
|---|---|---|---|---|---|---|---|---|---|---|---|---|---|
| Storage days | Day | 0 | 60 | 0 | 60 | 0 | 60 | 0 | 60 | 0 | 60 | 0 | 60 |
| Viscosity | cP | 2009 | 1820 | 2002 | 1939 | 2001 | 1953 | 2000 | 1967 | 2001 | 1971 | 2005 | 1932 |
| Change rate in viscosity | % | | −9.4 | | −3.1 | | −2.4 | | −1.7 | | −1.5 | | −3.6 |
| Degree of in-plane | % | 2.5 | 4.8 | 2.5 | 3.2 | 2.5 | 2.9 | 2.5 | 2.6 | 2.5 | 2.5 | 2.6 | 3.5 |
| uniformity of film | | | | | | | | | | | | | |
| thickness of heat- | | | | | | | | | | | | | |
| resistant resin film | | | | | | | | | | | | | |

TABLE 5

| Reference Example and | 101 | | 102 | | 103 | |
|---|---|---|---|---|---|---|
| Comparative Example | E | F | E | F | E | F |

| Synthesis Example | | | 107 | 108 | 109 |
|---|---|---|---|---|---|
| Acid | BPDA | Molar | 100 | 100 | |
| di- | PMDA | ratio | | | 100 |
| anhydride | | | | | |
| Diamine | PDA | | 100 | 100 | |
| compound | DAE | | | | 100 |
| Terminal | DIBOC | | 10 | | 10 |
| blocking | Ethanol | | | | |
| agent | Isopropyl | | | | |
| | alcohol | | | | |
| | tert-Butyl | | | 10 | |
| | alcohol | | | | |
| Catalyst | 1-Methyl | | | | |
| | imidazole | | | | |

| | | | | | | | |
|---|---|---|---|---|---|---|---|
| Storage days | Day | 0 | 60 | 0 | 60 | 0 | 60 |
| Viscosity | cP | 2008 | 2247 | 2002 | 1723 | 2000 | 2256 |
| Change rate | % | | +11.9 | | −13.9 | | +12.8 |
| in viscosity | | | | | | | |
| Degree of in-plane | % | 2.5 | 5.8 | 2.5 | 6.3 | 2.6 | 5.9 |
| uniformity of film | | | | | | | |
| thickness of heat | | | | | | | |
| resistant resin film | | | | | | | |

### Example 107

An organic EL display device was formed on the heat resistant resin film obtained in F of Example 101 in the same manner as Example 21.

When voltage was applied to the formed organic EL display device through a driving circuit, the organic EL display device provided excellent emission.

### Reference Example 104

An organic EL display device was formed on the heat resistant resin film obtained in F of Reference Example 101 in the same manner as Example 107. When voltage was applied to the organic EL display device through a driving circuit, however, unevenness in light emission occurred, which was poor.

### Example 201

To 50 g of the varnish obtained in Synthesis Example 1, a solution of 0.50 g (1.6 mmol) of TAG-1 dissolved in 1 g of NMP was added and the resultant liquid was filtered with a filter having a pore diameter of 0.2 μm. A polyimide film was prepared using the varnish after filtration. Here, the heating conditions of Inert Oven were as listed in Table 6. The tensile elongation, maximum tensile stress, and Young's modulus of the obtained polyimide film were measured.

### Examples 202 to 209

In accordance with Table 6, the same evaluation was carried out as Example 201 except that the types of the resins, the types of the thermal acid generators, and the heating conditions of Inert Oven were adequately changed.

### Reference Example 201 to 203

In accordance with Table 6, the same evaluation was carried out as Example 201 except that the thermal acid generators were not added and types of the resins and the heating conditions of Inert Oven were adequately changed.

The evaluation results of Examples 201 to 209 and Reference Examples 201 to 203 were listed in Table 6.

TABLE 6

| | | Thermal acid generator | | Heating | Tensile | Maximum | Young's |
|---|---|---|---|---|---|---|---|
| | | | Added | condition of | elongation | tensile | modulus |
| | Resin | Type | amount | Inert Oven | (%) | stress (MPa) | (GPa) |
| Example 201 | Synthesis | TAG-1 | 0.50 g | 220° C./30 min | 6.3 | 148 | 6.0 |
| | Example 1 | | (1.6 mmol) | | | | |
| Example 202 | Synthesis | TAG-2 | 0.58 g | 220° C./30 min | 6.5 | 151 | 6.0 |
| | Example 1 | | (1.6 mmol) | | | | |
| Example 203 | Synthesis | TAG-3 | 0.61 g | 220° C./30 min | 8.0 | 167 | 6.1 |
| | Example 1 | | (1.6 mmol) | | | | |
| Example 204 | Synthesis | TAG-4 | 0.70 g | 220° C./30 min | 8.1 | 170 | 6.1 |
| | Example 1 | | (1.6 mmol) | | | | |
| Example 205 | Synthesis | TAG-5 | 0.63 g | 220° C./30 min | 11.0 | 190 | 6.0 |
| | Example 1 | | (1.6 mmol) | | | | |
| Example 206 | Synthesis | TAG-6 | 0.72 g | 220° C./30 min | 11.5 | 201 | 6.0 |
| | Example 1 | | (1.6 mmol) | | | | |
| Example 207 | Synthesis | TAG-7 | 0.34 g | 220° C./30 min | 13.6 | 231 | 6.0 |
| | Example 1 | | (1.6 mmol) | | | | |
| Example 208 | Synthesis | TAG-7 | 0.34 g | 180° C./30 min | 8.6 | 177 | 6.0 |
| | Example 1 | | (1.6 mmol) | | | | |
| Example 209 | Synthesis | TAG-5 | 0.34 g | 220° C./30 min | 11.4 | 199 | 6.0 |
| | Example 101 | | (1.6 mmol) | | | | |
| Reference | Synthesis | None | | 220° C./30 min | 2.8 | 134 | 6.1 |
| Example 201 | Example 1 | | | | | | |
| Reference | Synthesis | None | | 180° C./30 min | 2.7 | 133 | 6.1 |
| Example 202 | Example 1 | | | | | | |
| Reference | Synthesis | None | | 220° C./30 min | 2.7 | 131 | 6.1 |
| Example 203 | Example 101 | | | | | | |

### Example 210

An organic EL display device was formed on the heat resistant resin film obtained in Example 201 in the same manner as Example 21. When voltage was applied to the formed organic EL display device through a driving circuit, the organic EL display device provided excellent emission.

### Reference Example 204

An organic EL display device was formed on the heat resistant resin film obtained in Reference Example 201 in the same manner as Example 21. However, in the process of peeling from the glass substrate, the mechanical strength of the heat resistant resin film was low and the film was broken, so that the subsequent evaluation was impossible to be carried out.

1. A resin composition comprising:
an (a) resin having a structure represented by Chemical Formula (1): 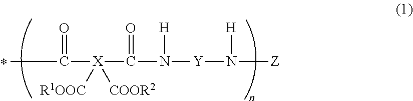
wherein in Chemical Formula (1), X represents a tetravalent tetracarboxylic acid residue having two or more carbon atoms and Y represents a divalent diamine residue having two or more carbon atoms; Z represents a structure represented by Chemical Formula (2); n represents a positive integer; R¹ and R² each independently represent a hydrogen atom, a hydrocarbon group having 1 to 10 carbon atoms, an alkylsilyl group having 1 to 10 carbon atoms, an alkali metal ion, an ammonium ion, an imidazolium ion, or a pyridinium ion; and * indicates that the carbon atom is bonded to another atom; 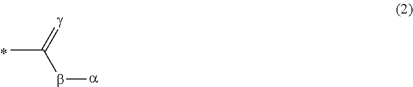
wherein in Chemical Formula (2), α represents a monovalent hydrocarbon group having 2 or more carbon atoms and β and γ each independently represent an oxygen atom or a sulfur atom; and * indicates a bonding point of Z in Chemical Formula (1); and
a (b) solvent, wherein
the resin composition additionally comprises an amount of a compound represented by Chemical Formula (3) of 0.1 ppm by mass or more and 40 ppm by mass or less, 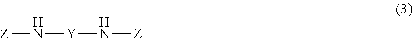
wherein in Chemical Formula (3), Y represents a divalent diamine residue having 2 or more carbon atoms; and Z represents a structure represented by Chemical Formula (2).

2. The resin composition according to claim 1, wherein the amount of the compound represented by Chemical Formula (3) is 4 ppm by mass or more.

3. A resin composition comprising:
an (a′) resin having a repeating unit represented by Chemical Formula (4) as a main component; and
a (b) solvent, wherein
the (a′) resin comprises one or more resins selected from a group consisting of the following (A) and (B):
(A) a resin mixture comprising a resin (A-1) comprising two or more partial structures represented by Chemical Formula (5) in a molecule and a resin (A-2) comprising two or more partial structures represented by Chemical Formula (6) in a molecule; and
(B) a resin comprising one or more partial structures represented by Chemical Formula (5) and one or more partial structures represented by Chemical Formula (6) in a molecule, 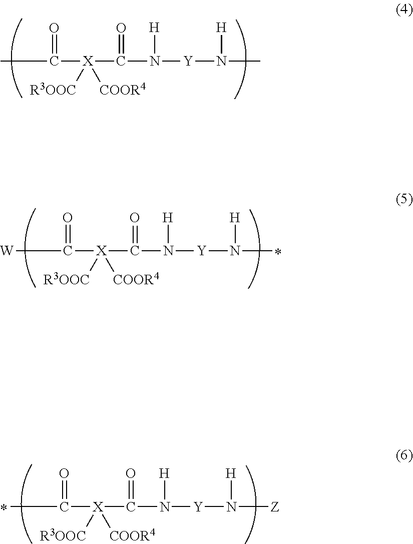
wherein in Chemical Formulas (4) to (6), X represents a tetravalent tetracarboxylic acid residue having two or more carbon atoms and Y represents a divalent diamine residue having two or more carbon atoms; in Chemical Formula (5), W represents a structure represented by Chemical Formula (7); Z represents a structure represented by Chemical Formula (2); R³ and R⁴ each independently represent a hydrogen atom, a hydrocarbon group having 1 to 10 carbon atoms or an alkylsilyl group having 1 to 10 carbon atoms, an alkali metal ion, an ammonium ion, an imidazolium ion, or a pyridinium ion; and * in Chemical Formulas (5) and (6) indicates that the nitrogen/carbon atom is bonded to another atom, 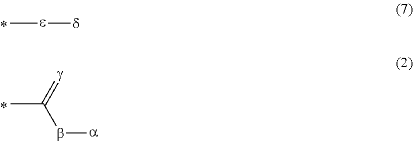
wherein δ in Chemical Formula (7) and a in Chemical Formula (2) each independently represent a monovalent hydrocarbon group having two or more carbon atoms; E in Chemical Formula (7) and β and γ in Chemical Formula (2) each independently represent an oxygen atom or a sulfur atom; * in Chemical Formula (7) indicates a bonding point of W in Chemical Formula (5) and * in Chemical Formula (2) indicates a bonding point of Z in Chemical Formula (6).

4. The resin composition according to claim 1, wherein β and γ in Chemical Formula (2) are oxygen atoms.

5. The resin composition according to claim 1, wherein α in Chemical Formula (2) is a tert-butyl group.

6. The resin composition according to claim 1, further comprising a (c) thermal acid generator.

7. A method for producing a resin represented by Chemical Formula (1), the method comprising:
(A) a step of producing a compound represented by Chemical Formula (41) by gradually adding a solution in which a terminal amino group blocking agent that is reactive with an amino group of a diamine compound is dissolved in a reaction solvent in 20% by mass or less to the diamine compound over a time of 10 minutes or more; 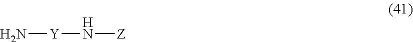
wherein in Chemical Formula (41), Y represents a divalent diamine residue having two or more carbon atoms; and Z represents a structure represented by Chemical Formula (2), 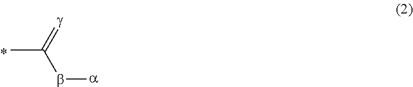
wherein in Chemical Formula (2), a represents a monovalent hydrocarbon group having 2 or more carbon atoms and β and γ each independently represent an oxygen atom or a sulfur atom; and * indicates a bonding point of Z in Chemical Formula (41); and
(B) a step of reacting the compound represented by Chemical Formula (41), at least one compound selected from the group consisting of a tetracarboxylic acid, a tetracarboxylic dianhydride, an active ester of a tetracarboxylic acid, and an active amide of a tetracarboxylic acid, and a residual diamine compound having not reacted with the terminal amino group blocking agent in the (A) step, 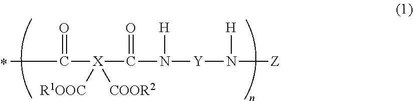
wherein in Chemical Formula (1), X represents a tetravalent tetracarboxylic acid residue having two or more carbon atoms and Y represents a divalent diamine residue having two or more carbon atoms; Z represents a structure represented by Chemical Formula (2); n represents a positive integer; R¹ and R² each independently represent a hydrogen atom, a hydrocarbon group having 1 to 10 carbon atoms, an alkylsilyl group having 1 to 10 carbon atoms, an alkali metal ion, an ammonium ion, an imidazolium ion, or a pyridinium ion; and * indicates that the carbon atom is bonded to another atom).

8. (canceled)

9. (canceled)

10. (canceled)

11. A method for producing a resin film, the method comprising:
a step of applying the resin composition according to claim 1 to a support; and
a step of heating the obtained applied film at a temperature of 220° C. or more.

12. A method for producing an electronic device, the method comprising:
a step of forming a resin film by the method according to claim 11; and
a step of forming an electronic device on the resin film.

13. The method for producing an electronic device according to claim 12, wherein the electronic device is an image display device.

14. The method for producing an electronic device according to claim 12, wherein the electronic device is an organic EL display.

15. The resin composition according to claim 3, wherein β and γ in Chemical Formula (2) are oxygen atoms.

16. The resin composition according to claim 3, wherein α in Chemical Formula (2) is a tert-butyl group.

17. The resin composition according to claim 3, further comprising a (c) thermal acid generator.

18. A method for producing a resin film, the method comprising:
a step of applying the resin composition according to claim 3 to a support; and
a step of heating the obtained applied film at a temperature of 220° C. or more.
